(19) United States
(12) Patent Application Publication
(10) Pub. No.: US 2009/0308001 A1
(43) Pub. Date: Dec. 17, 2009

(54) Substrate and the application

(75) Inventors: Shaobing Wu, Jamestown, NC (US); Shaoyun Wu, Shenzhen (CN); Frank Wu, Jamestown, NC (US); Alderik Wu, Jamestown, NC (US)

Correspondence Address: Shaobing Wu, 3852 Windstream Way, Jamestown, NC, 27282, US

(73) Assignee: Shaobing Wu, Jamestown, NC (US)

(21) Appl. No.: 12/410,574

(22) Filed: Mar. 25, 2009

(30) Foreign Application Priority Data
Jun. 16, 2008 (CN) 200810067849.5

(51) Int. Cl. H01L 31/0216; E04B 2/32; E04C 2/20; E04B 1/66

(52) U.S. Cl. 52/173.3; 52/588.1; 52/309.4; 52/311.1; 52/741.4

(57) ABSTRACT

This invention relates to a substrate and the application. In particular, this invention discloses a substrate which has at least one contact structure at least on one side and at least one contact structure at least on one surface of the substrate. The substrate includes a thermal insulation material comprising at least two materials selecting from a thermal energy reflecting material, a homogeneous foam material, a heterogeneous foam material, a skin material, a skeleton structured material, an electromagnetic wave shielding material. The substrate may be used to construct various articles with different features of energy saving, decoration and protection as well as simple installation for various applications.

### RELATED APPLICATIONS

This application claims priority from China Patent Application Serial Number CN 200810067849.5, filed on Jun. 16, 2008, the disclosure of which is incorporated herein by reference.

### FIELD OF THE INVENTION

This invention relates to a substrate and the use for various applications in energy saving, decoration and protection.

### BACKGROUND OF THE INVENTION

As demand for energy has been skyrocketing over the past decades, the cost of energy to maintain heating in the winter or cooling in the summer for buildings and homes has become a big budge and expense across the global. In the Western countries, vinyl sheets, engineered wood boards, high density fiber boards, cement fiber boards or metal sheets have been the traditional external covering materials for residential homes while bricks, ceramic tiles, glass, stone, marbles, and metal sheets are the conventional major protective and decorative materials for commercial high rises and corporate buildings. In the Far East countries, bricks, stones, ceramic tiles, marbles and concrete finishing have been long used as the protective and decorative construction materials for both the residential and commercial buildings. Although conventional building materials have advantages of natural beauty, appealing look and appearance, the materials are high in cost, high in energy consumption, poor in heat insulation, and cumbersome in installation. Vinyl, high density fiber boards, cement fiber boards are easier to be installed and lower in cost, however, they lost the look and appearance of conventional building materials and still are poor in heat insulation and energy saving.

There have been a number of attempts to change the traditional way of using conventional building materials and improve the energy efficiency by incorporating a thermal insulating material for constructions of buildings. U.S. Pat. Nos. 5,842,276, 6,167,624 teach methods to make a polymeric insulation structure panel by cutting a synthetic foam material (expanded polystyrene) to form slots for receiving brace members (metal or wood) and dispose brace members into slots to form a polymeric foamed material panel as a load-bearing and insulating panel for construction of exterior, interior walls or roofs of a building. U.S. Pat. No. 6,854,228 discloses a composite insulating panel comprising an insulating foam core material sandwiched between an outer board and a skin material capable of radiating heat. The outer board material is a structure material such as plywood, oriented strand board (OSB) or gypsum board and the skin material is an aluminum foil. The composite insulating panel is used as a structure board and to be installed onto building frames to form interior or exterior walls of a building. Although those attempts made improvement in terms of the energy efficiency, there are still many challenges that need to be solved:

1) The insulating panels from the prior arts and techniques were still designed for traditional applications and still required additional decorative and protective materials applied over the panels to finish a building.

2) The cost and complexity of the fabrication from the prior arts and techniques and the cost of the overall finishing process and limited benefits for a building during the construction still prevent the prior arts and techniques from substituting or replacing conventional high energy consuming building products.

3) Conventional building materials such as ceramic tile, glass plates, metal plates, and mortar wall finishes still present ongoing issues of leaking and cracking along edges, falling and separating from building, cracking due to inherent building body movements, and complexity of installation or finishing process in addition to high cost and high energy consuming. Particularly, the cracks and falling of the panels from the buildings not only diminish the look, appearance and quality of the buildings but also can allow water and moisture to penetrate through cracks, joints, or boundaries, which can eventually cause severe damages to the building structures.

4) The heat insulation materials for the insulating panels of the prior art and old techniques are made and sliced from bulk polystyrene or polyurethane foam planks. The cutting process apparently cause foam structure damages which can significantly reduce the mechanical strength of the panels and increase water or moisture penetration along the cutting surfaces. In order to enhance the mechanical strength of the panels, one or more layers or braces or frames of reinforcing or supporting materials, such as, cement, concrete gypsum, fiber glass, metal are required and incorporated. Unfortunately, these techniques not only make the panels heavy and difficult to install but also make the manufacture process complicated and expensive.

5) The installation of the insulating panels of the prior art and techniques and conventional building materials relies on limited chemical bonding of an adhesive applied onto a flat surface on the back of the panels or mechanical bonding using nails or screws applied through the panels to achieve the securing. Therefore, the installation of those panels from the prior art and techniques including conventional building materials is not effective and efficient.

6). Safety and security have increasingly become a growing concern especially for radiation generating buildings, government buildings, and security agencies as nowadays the world becomes an electronic and digital world. In such a situation, the decorative panels of the prior art and techniques don't have a function against electronic magnetic wave intrusion, penetration, escaping, or radiation.

None of foregoing techniques or prior arts teaches a technique to make a decorative and protective panel that is efficient, protective and decorative while the panel is less complicated for installation. Most importantly, it is imperative to discover a method to make an energy saving building material that can provide a maximized energy saving feature as we are facing the fact that the fossil fuels are depleting and the global warming is threatening the earth.

Accordingly, it is an object of the present invention to provide a substrate which can be constructed into various articles and the articles can be used for various applications in energy saving, protection and decoration. It is another object of the present invention to provide a substrate from which articles can be simply and securely installed on various objects. Yet, it is another object of the present invention to provide a method to effectively utilize solar energy for heating, cooling, or generating electricity so that the energy demand from fossil fuels can be reduced. Yet, it is still another object to provide a decorative panel that has the look and appearance of a conventional building material so that the natural beauty of the traditional building materials can be preserved. Yet, it is still another object to provide a decorative panel that is capable of reducing or eliminating electromagnetic wave intrusion, penetration, escaping or radiation.

### SUMMARY OF THE INVENTION

In general, the present disclosure is directed to a substrate and the application. Specifically, the substrate comprises contact structures and thermal insulation materials. The substrate has at least one contact structure on one of the sides and at least one contact structure on the back, face or both of the surfaces of the substrate. The thermal insulation materials comprises at least two materials selecting from thermal reflecting materials, homogenous foam materials, heterogeneous foam materials, skin materials, skeleton structured materials and at least one of the materials is flame resistant, contains flame retardants, or comprises polyvinyl chloride or recycled materials. The substrate may be constructed into various articles comprising a substrate and a protective and decorative material or device. The protective and decorative materials may be a material selecting from materials having the look and appearance of a conventional building material, electromagnetic wave shielding materials, air purifying materials, solar-thermal energy converting materials or devices, solar-lighting materials or devices, or solar-electricity converting materials or devices. The materials having the look and appearance of a conventional building material may be a conventional building material or a material with an artificial pattern made from a process comprising at least one process selecting from roller embossing, pressing, stamping, or computer aided printing processes to simulate the pattern of a conventional building material. The resultant articles with different application features including energy saving, protection and decoration may be simply installed on various objects with an adhesive, connection device or combination of an adhesive and connection device.

The present disclosure thus provides, in one aspect, a substrate including one or more contact structures on the sides and at least one contact structure on back, face or both of the back and face of the substrate. The contact structure may have an outward configuration such as tongue or inward configuration such as groove.

The present disclosure thus provides, in another aspect, a substrate including a secondary contact structure on a first contact structure. The secondary contact structure may have an outward configuration such as tongue or inward configuration such as groove.

The present disclosure thus provides, in yet another aspect, a substrate containing thermal insulation materials comprising at least two materials selecting from thermal reflecting materials, homogenous foam materials, heterogeneous foam materials, skin materials, and skeleton structured materials and at least one material is flame resistant contains flame retardants, or a recycled material. The thermal reflecting materials may be, but not limited to, a metallic film, foil, sheet or a coating capable of reflecting heat. The foam material may be a homogeneous or heterogeneous foam material comprising polymeric resins, blowing agents, activators, stabilizers, fillers, modifiers, additives, colorants, and the like. The skin materials are a layer of materials formed on at least one surface of the thermal insulation materials or the substrate. The skeleton materials are materials formed into at least one three dimensional skeleton structure of a geometric shape within the thermal insulation materials and the spaces within the skeleton structures may be filled with a gas or a foam material.

The present disclosure provides, in yet another aspect, an article including a substrate and a layer of protective and decorative materials comprising a material having the look and appearance of a conventional building material. The material having the look and appearance of a conventional building material may be a conventional building material or a material made with an artificial pattern.

The present disclosure provides, in yet another aspect, a method for making an article with artificial patterns from a process comprising at least one process selecting from embossing, pressing, stamping, or computer aided printing processes.

The present disclosure provides, in yet another aspect, an article including a substrate and a layer of protective and decorative materials comprising heat, moisture, enzyme, or photo-initiated or activated components to eliminate or reduce unhealthy or toxic air smog, air pollutants, or unpleasing odors or to provide color changes or illuminate differently under a different condition.

The present disclosure provides, in yet another aspect, an article including a substrate and a layer of functional, protective and decorative materials comprising an electromagnetic wave shielding material. The electromagnetic waves shielding material is a material that can prevent electromagnetic waves from penetrating to or emitting from an object and typically comprises a metallic film, foil, sheet, a composite or a coating containing metallic flakes, pellets, fibers, nets, fabrics, powders, metal oxides, or combinations thereof.

The present disclosure provides, in yet another aspect, an article including a substrate and a layer of functional, protective and decorative materials comprising solar-thermal energy converting materials or device, solar lighting materials or device, or solar-electricity converting materials or device.

The present disclosure provides, in yet another aspect, a method for making a substrate with contact structures from a process comprising extrusion, injection, molding, cutting, sanding, bonding, or combinations thereof.

The present disclosure provides, in yet another aspect, a method for finishing an exterior or interior surface of a building or any surface of an object, comprising a substrate or an article and adhesive, a connection device or combinations thereof.

The present disclosure thus provides, in yet another aspect, a method for reducing global warming and increasing energy efficiency, including making and installing a substrate or the resultant articles from a substrate of the present invention which are energy saving, protective and decorative as well as simply installation, which method comprises using a substrate or the resultant articles of the present invention to replace conventional high energy consuming building materials such as bricks, marbles, ceramics, glass, metals, and the like and those conventional low energy saving vinyl sidings, cement fiber boards, engineered wood board, and the like.

The above summary of the present invention is not intended to describe each disclosed embodiment or every implementation of the present invention. In addition to the advantages as summarized above, other features, objects, and advantages of the invention will be apparent from the description and drawings, and from the claims. The description that follows more particularly exemplifies illustrative embodiments. In several places throughout the application, guidance is provided through lists of examples, which examples may be used in various combinations. In each instance, the recited list serves only as a representative group and should not be interpreted as an exclusive list. For a more complete understanding of the present invention, the reader is referred to the following detailed description section which should be read in conjunction with the accompanying drawings.

### BRIEF DESCRIPTION OF THE DRAWINGS

The present invention is described in more detailed hereinafter with reference to the accompanying drawings wherein like reference characters refer only to the parts within the same views of the drawings and in which:

FIG. 1 is a cross-sectional side view of a substrate and a decorative panel 10 based on the substrate of the present invention installed using an adhesive 14 on a wall 18 of a building in accordance with the present invention;

FIG. 2 are perspective views of an outward contact structure 19 and an inward contact structure 20 in the sides or the back, face or both the back and face of the substrate of the present invention, respectively in accordance with the present invention;

FIG. 3 are cross-sectional side views of exemplary outward and inward contact structures 21, 22, 23, 24, 25, 26 on the sides and cross-sectional side views of exemplary different secondary contact structures 27 in accordance with principles of the present invention;

FIG. 4 are cross-sectional side views of exemplary inward contact structures 28, 29, 30 and outward contact structures 31, 32, 33 in accordance with the present invention;

FIG. 5 are cross-sectional side views of exemplary inward contact structures 34, 35, 36 and outward contact structures 37, 38, 39 in accordance with the present invention;

FIG. 6 are over views of exemplary arrangements and distributions 40, 41, 42, 43 of a contact structure on the surface (back, face or both the back and face) of a substrate;

FIG. 7 are cross-sectional side views of different thermal insulation materials 44, 45, 46, 47 for a substrate in accordance with embodiments of the present invention;

FIG. 8 is a perspective view of a connection device 49 comprising a hook mechanism 50 in accordance with the principles of the present invention;

FIG. 9 are cross-sectional side views of a connection device 52 or 53 with a self expandable head and an irreversible locking or one way movable locking mechanism 55 vertically or horizontally under a pressure and to be used for installation of a substrate or an article with a contact structure 51 on the back of the substrate or article;

FIG. 10 is a cross-sectional side view of an extruded substrate with a heterogeneous foam 60 as the thermal insulation material and the contact structures on the sides 57, 58 and back 59 of the substrate in accordance with an embodiment of the present invention;

FIG. 11 is a cross-sectional side view of an extruded substrate with a foam 61 filled skeleton 62 structured thermal insulation material and the contact structures 57, 58, 59 on the sides and back of the substrate in accordance with an embodiment of the present invention.

FIG. 12 is a cross-sectional view of an extruded contact structure profile 63 with an outward contact structure 57 and inward contact structure 58;

FIG. 13 is a perspective view of a modeled panel substrate 64 with the contact structures on the sides and back of the substrate;

FIG. 14 is a cross-sectional side view of an extruded decking board 65 with contact structures on the sides and back of the board in accordance with an embodiment of the present invention.

### DETAILED DESCRIPTION

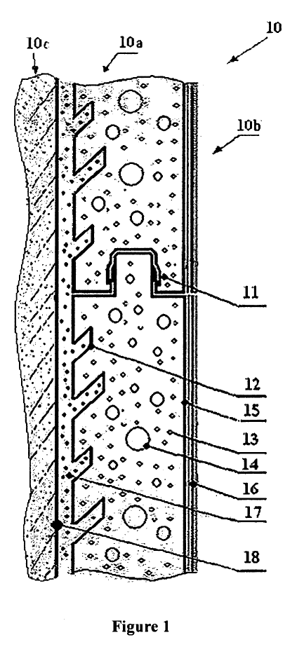

Thus, a finished system 10 comprising an energy saving, decorative and protective panel 10b based on a substrate 10a, an adhesive 17 and a surface 18 of a building 10c is illustrated in FIG. 1. The energy saving, decorative and protective panel 10b based on a substrate 10a and a layer of decorative and protective materials 16 is installed using an adhesive 17 on the wall surface 18 of a building 10c. The substrate 10a comprises a contact structure 11 on the sides, a contact structure 12 on the back of the substrate, and a thermal insulation material including heterogeneous foam materials 13, 14 and a skin material 15 in accordance with an embodiment of the present invention.

The term “substrate” is a backing and supporting material upon which a decorative and protective finish or a functional device is applied to construct and form various articles for various applications;

The term “side” means a plane along the edges of a panel substrate, for instance, a rectangular panel has four sides along the edges in addition to two surfaces, one surface is termed as a “face” and the other is termed as a “back”;

The term “contact structure” means a three dimensional configuration formed on one or more sides and/or the back or face or both the back and face of a substrate to provide one or more physical actions of connecting, jointing, locking, bonding, linking, sealing or combinations thereof upon contacts;

The term “contact” means a physical interaction of “adhering, touching, locking, anchoring, inserting, penetrating, or combinations thereof between different surfaces;

The term “article” means a product entity or assembly that is based on a substrate and made to perform an certain function(s) such as energy saving, energy generating, electromagnetic wave shielding, color changing, air purifying, light illuminating, decoration, protection, or combinations thereof;

The term “panel” means a panel which may two surfaces (face or back) and side(s) in certain length, width and thickness as desired and may, may not be a flat form, may have partial or complete circle, arc, angled, oval, curved surfaces, or combinations thereof;

The terms “a,” “an,” “the,” “at least one,” and “one or more” are used interchangeably. Thus, for example, a substrate that comprises “a” contact structure can be interpreted to mean that the substrate includes “one or more” contact structures;

The terms “preferred” or “desirable: and “preferably” or “desirably” refer to embodiments of the invention that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the invention;

The recitation of numerical ranges by endpoints includes all numbers subsumed within that range (e.g., 1 to 5 includes 1, 1.25, 2, 2.75, 3, 3.80, 4, 5, etc.); The terms “resin” and “polymer”, “polymer resin” are used interchangeably;

The term “vinyl chloride resins” means those homo and copolymers of vinyl chloride or vinylidene chloride as well as chlorinated homo and copolymers;

The term “phr” means parts by weight per hundred parts of resin(s);

The term “EDP” refers to “energy saving, decorative and protective”,

The term “FDP” refers to “functional, decorative and protective”.

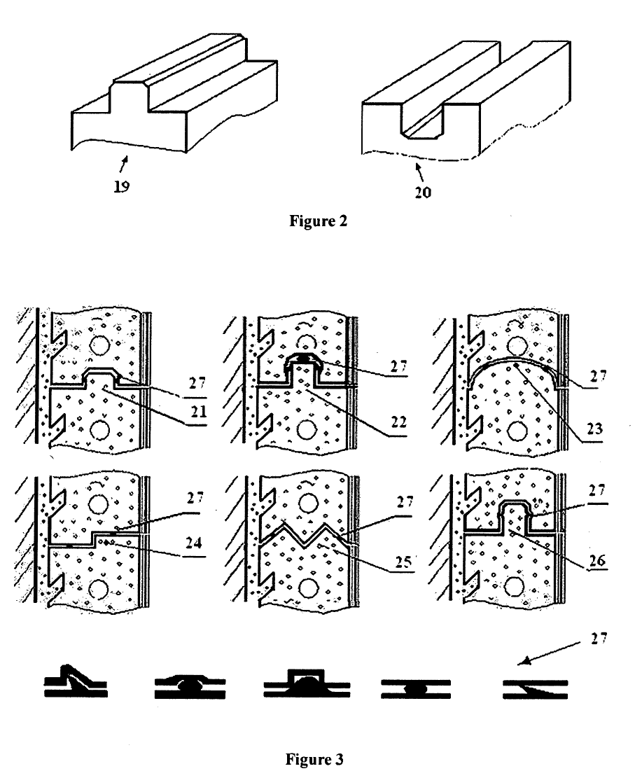

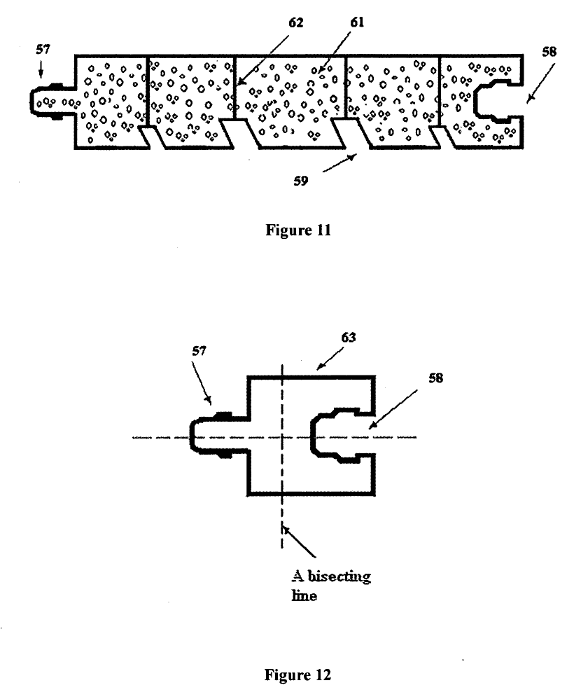

In general, the present disclosure is directed to a substrate (FIG. 1) and the application for various articles which are made from the substrate. A substrate of the present invention comprises a contact structure on the sides (FIGS. 1, 11), a contact structure on the back, face or both the back and face (FIGS. 1, 12), and a thermal insulation material (FIGS. 1, 13, 14). The contact structure may be an outward contact structure (FIGS. 2, 19), such as, a tongue structure or may have an erected three dimensional configuration of which the cross-section, perpendicular to the face of the substrate, may comprise any partial or complete, regular or irregular polygon, triangle (right, equilateral, equiangular, isosceles, scalene, acute, obtuse), quadrilateral, square, rectangle, parallelogram, rhombus, trapezoid, pentagon (regular or irregular), hexagon, heptagon, octagon, circle, arc, angular, oval, curve, or combinations thereof (FIGS. 3, 21-26). The term “tongue structure” means a three dimensional, long or short, narrow or wide, high or low projected or erected structure above one plane which may be able to receive a groove structure from another object.

The contact structure may be an inward contact structure (FIGS. 2, 20), such as, a groove structure or may have a recessed three dimensional configuration of which the cross-section, perpendicular to the face of the substrate, may comprise any partial or complete, regular or irregular polygon, triangle (right, equilateral, equiangular, isosceles, scalene, acute, obtuse), quadrilateral, square, rectangle, parallelogram, rhombus, trapezoid, pentagon (regular or irregular), hexagon, heptagon, octagon, circle, arc, angular, oval, curve, or combinations thereof (FIGS. 3, 21-26). The term “groove contact structure” means a three dimensional long or short, narrow or wide cut or indented or recessed structure below one plane which may be able to receive a tongue structure from an object.

A contact structure on one side of a substrate may form a connection with a contact structure on one side of another substrate upon the direct contacts or indirect contacts. Desirably, an outward contact structure on one side of a substrate may form a connection with an inward contact structure on one side of another substrate upon the direct contacts. It may be acceptable for a contact structure on one side of a substrate to form a connection with the same or different contact structure on one side of another substrate upon an indirect contact. The indirect contact herein means a contact is achieved between the contact structures through a connection material such as a sealant, adhesive or materials including wedges, nails or screws.

Optionally, a contact structure on the side(s) and on the back or face of a substrate of the present invention may constitute one or more secondary contact structures on any part of a primary contact structure on the sides and/or on the back, face or both the back or face of a substrate. A secondary contact structure may be an outward, inward, or combinations of the outward and inward contact structures (FIGS. 3, 27). A secondary outward contact structure may be a tongue configuration or may have an erected three dimensional configuration of which the cross-sectional view, perpendicular to the face of the substrate, may comprise any partial or complete, regular or irregular polygon, triangle (right, equilateral, equiangular, isosceles, scalene, acute, obtuse), quadrilateral, square, rectangle, parallelogram, rhombus, trapezoid, pentagon (regular or irregular), hexagon, heptagon, octagon, circle, angular, arc, oval, curve, or combinations thereof (FIGS. 3, 27). A secondary inward contact structure may be a groove configuration or may have a recessed three dimensional configuration of which the cross-sectional view, perpendicular to the face of the substrate, may comprise any partial or complete, regular or irregular polygon, triangle (right, equilateral, equiangular, isosceles, scalene, acute, obtuse), quadrilateral, square, rectangle, parallelogram, rhombus, trapezoid, pentagon (regular or irregular), hexagon, heptagon, octagon, circle, arc, angular, oval, curve, or combinations thereof (FIGS. 3, 27). A secondary contact structure may have the same or different configuration from the configuration of the primary contact structure. The material for a secondary contact structure may be the same or different from the material of the primary contact structure. The formation of a secondary contact structure may be processed concurrently or separately from the formation of the primary contact structure.

Preferably, a substrate may have at least one contact structure at least on one side. More preferably, a substrate may have an outward contact structure at least on one side and an inward contact structure at least on another side. Most preferably, a substrate may have both the inward and outward contact structures on all sides of the substrate; for example, a substrate may have one outward contact structure on two sides and one inward contact structure on the other two sides. Desirably, an outward contact structure on one side of a substrate may adapt into an inward contact structure on one side of another substrate and form connections upon direct contacts or indirect contacts. More preferably, an outward contact structure on one side of a substrate may lock into an inward contact structure on one side of another substrate and form connections upon direct contacts. Most preferably, an outward contact structure on one side of a substrate may adapt and lock into an inward contact structure on one side of another substrate and form connections upon direct contacts without using any other materials.

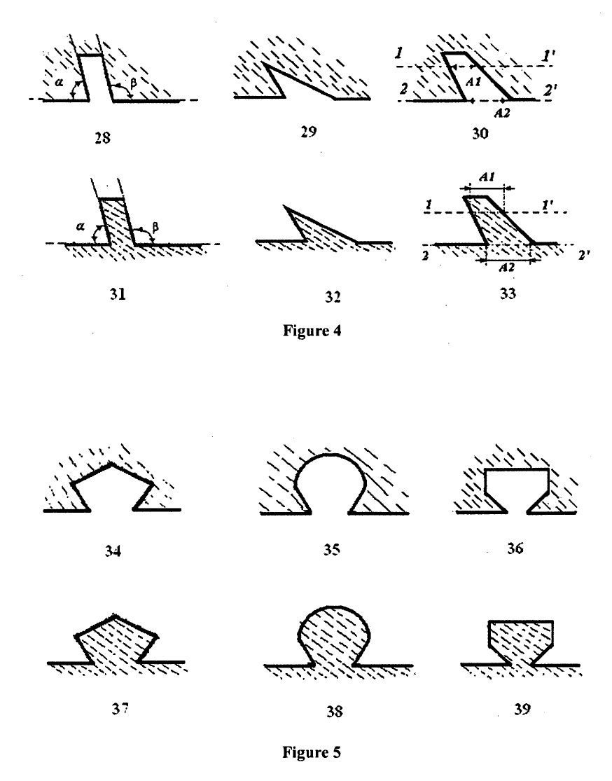

A substrate may have at least one contact structure on the back, face or both of the face and back of the substrate. Desirably, a substrate may have at least one contact structure on the back of the substrate. Similarly, a contact structure on the back or face of the substrate may be an inward, outward contact structure or combinations thereof. Preferably, an inward contact structure (FIGS. 4, 28-30) or an outward contact structure (FIGS. 4, 31-33) on the back, face or both of the surfaces of the substrate may have a configuration of which one of the angles, such as the angles α, β in FIGS. 4, 28 and 33, forming between a surface of a contact structure and the surface of the substrate may be smaller or greater than 90 degree. Preferably, a smaller angle (α) of the contact structure may be between 5° and 89°, more preferably may be at or between 10° and 80°, most preferably at or between 20° and 70° (FIGS. 4, 28-33).

Any part of a contact structure on a substrate may desirably include a smooth or transitional surface, such as a rounded, arced surface instead of a sharp or angular surface change to simplify the formation process and reduce any stress caused damage to the integrity of the substrate. Different configurations of a contact structure for a substrate may offer different benefits. For example, a substrate may provide benefits of easier fabrication of the contact structures and possibility of replacement of an article made from a substrate with a contact structure on the back of a substrate comprising a configuration (FIGS. 4, 28-33) wherein the inner cross-sectional area (A1 in the cross-section 1-1′ in FIG. 4, c), parallel to the back of the substrate, of an inward contact structure inside of the substrate is equal to or smaller than the outer cross-sectional area (A2 in the cross-section 2-2′ in FIGS. 4, 30), parallel to the surface of the substrate, of the inward contact structure on the surface of the substrate or a configuration (FIGS. 4, 34-39) wherein the upper cross-sectional area (A1 in the cross-section 1-1′ in FIGS. 4, 39), parallel to the surface of the substrate, of an outward contact structure is equal to or smaller than the lower cross-sectional area (A2 in the cross-section 2-2′ in FIGS. 4, 39), parallel to the surface of the substrate, of the outward contact structure on the surface of the substrate.

Similarly, a substrate may provide benefits of permanent or irreversible installation of an article made from a substrate with a contact structure on the back of a substrate comprising a configuration (FIGS. 5, 34-39) wherein part of the inner cross-sectional areas, parallel to the back of the substrate, of an inward contact structure inside of the substrate is greater than the outer cross-sectional area, parallel to the surface of the substrate, of the inward contact structure on the surface of the substrate or a configuration (FIGS. 5, 37-39) wherein part of the upper cross-sectional areas, parallel to the surface of the substrate, of an outward contact structure outside of the substrate, is greater than the lower cross-sectional area, parallel to the surface of the substrate, of the same outward contact structure on the surface of the substrate.

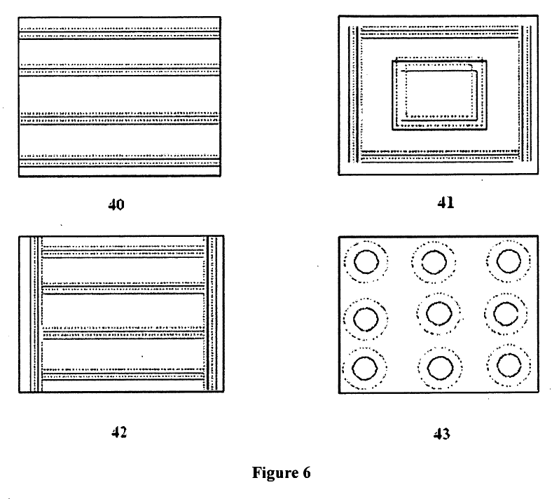

A contact structure on the back or face of a substrate may be arranged randomly or in an order of regularity and uniformity (FIG. 6). Desirably, all the contact structures are arranged orderly and uniformly to achieve best connections and simple process feasibility. Examples of arrangements and distributions of a contact structure on the back of a substrate may be one directional such as parallel to each other from one side to the other side (FIGS. 6, 40), two directional such as crosswise (FIGS. 6, 41-42) or evenly (FIGS. 6, 43).

The dimensions of each outward or inward contact structure may be made in various sizes as needed according to the number of the contact structures, specific configurations of the contact structures and the sizes of the panel. The depth of an inward contact structure or the height of an outward contact structure on the sides of a substrate may be the same or different. The minimum and maximum depth of an inward contact structure or the minimum and maximum height of an outward contact structure on the sides may be at or between 2% and 1000%, preferably at or between 5% and 500%, more preferably at or between 10% and 400%, the most preferably at or between 20% and 300% of the thickness of the panel. The minimum and maximum depth of an inward contact structure on the back, face or both the back and face may be at or between 0.01% and 99%, preferably at or between 0.1% and 90%, more preferably at or between 1% and 80%, the most preferably at or between 5% and 60% of the thickness of the panel. The minimum and maximum height of an outward contact structure on the back, face or both the back and face may be at or between 1% and 1000%, preferably at or between 2% and 500%, more preferably at or between 5% and 250%, the most preferably at or between 10% and 100% of the thickness of the panel.

A substrate may have one or more continuous contact structures, such as a ditch, pitch, from one point to another point on the substrate arranging evenly or irregularly on the sides, back, and/or face of the substrate. A substrate may have one or more discontinuous contact structures, such as a hole, crater, pit, cube, corn, cylinder, arranging uniformly or randomly on the sides, back, and/or face substrate. A substrate may have both continuous and discontinuous contact structures regularly or irregularly distributed on the substrate on the sides, back, and/or face substrate. A thick substrate, for example more than ¼ inches thick, may preferably have an inward contact structure on the back, face or both the back and face while a thinner substrate may have an outward contact structure on the back, face or both the back and face of the substrate.

Desirably, a substrate may have at least one continuous or discontinuous contact structure on the back, face or both the back and face of the substrate. The number of the contact structures on the sides, back, and/or face substrate may vary as desired. For example, the number of contact structures on the back of a substrate may be determined by the total cross-sectional area, parallel to the back of the substrate, of the contact structures required to achieve adequate connections. The minimum and maximum total cross-sectional areas of the contact structure may be at or between 1 and 99%, preferably at or between 10% and 90%, more preferably at or between 20% and 80%, the most preferably at or between 30% and 70% of the total surface area on the back of the substrate.

The materials for a contact structure of a substrate may be the same or different from the substrate or the thermal insulation materials. The material for each contact structure may be the same or different. The formation of the contact structures on the sides, back and face of a substrate may be concurrent or stepwise involving several steps and various processing methods may be suitable, for example, but not limited to extrusion, injection, casting, molding, calendaring, heat pressing, rolling, or combinations thereof. In addition, mechanical methods, such as, but not limited to, cutting, sawing, scrapping, drilling, scuffing, sanding, soldering, welding, bonding, hot-melting, gluing and the like, may be suitable too.

The thermal insulation materials for a substrate of the present invention may include a number of materials to enhance the thermal insulation property against energy loss from convection, conduction, and irradiation. The thermal insulation property of a material may be measured by thermal resistivity (R) or thermal conductivity (k) which may be determined by ASTM C518. The “R” value is the reciprocal of the “k” value which is commonly expressed in terms of the number of BTUs of heat which travels through one sq. foot of a material which is one inch thick when there is one degree F. temperature difference across the material (i.e. Delta T) in btu/in/hr/sq.ft/° F. Therefore, the higher the “R” value, the better the thermal insulation property against energy loss. Suitable thermal insulation materials for a substrate of the present invention may include a material capable of reflecting thermal energy or reducing/eliminating irradiated energy, such as infrared (IR) from emission or penetration. The materials capable of reflecting thermal energy may be, but not limited to, a metallic foil, film, sheet, plate which may be made from, but not limited to, aluminum, zinc, chromium, copper, stainless steel and the like. These thermal energy reflecting materials may further include a layer of clear polymeric materials such as, but not limited to, polyolefin (polyethylene, polypropylene, ethylene-vinylacetate copolymer, and the like), polyurethane, epoxy, polyesters and the like, for enhanced protection and/or inter-adhesion during the application. These materials may be applied onto any surface layer or cross-section of a substrate by an adhesive bonding or hot pressing. The materials capable of reflecting thermal energy may be also a metallic coating or a coating comprising thermal energy reflection components, metallic powders, flakes, metal coated pigments, additives and the like. Examples, but not limited to, are aluminum, copper, chromium powders, flakes, metallic coated or treated mica, glass beads and the like. The coating may be applied onto any part of a substrate by any of the coating methods, such as, spray, brush, roller, and the like. In addition, a coating therein may be simply a layer of metals formed through a coating process such as electroplating, vacuum vapor deposition and the like.

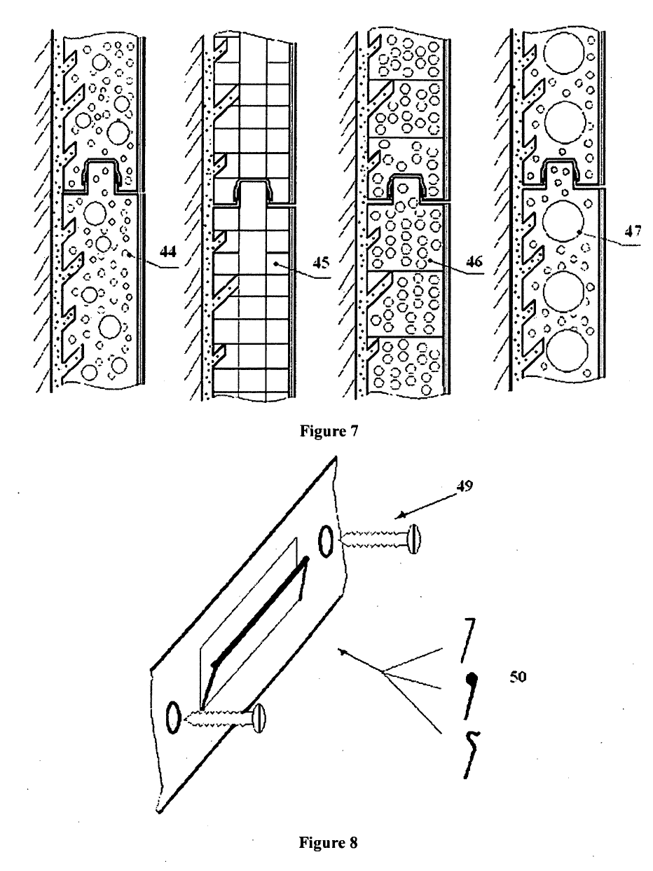

The thermal insulation materials for a substrate of the present invention may comprise a foam or cellular material. In terms of the cellular structures and uniformity of the cellular sizes, a foam material may be homogeneous or heterogeneous. A homogeneous foam material may comprise one material with substantially the same cellular shapes and sizes, whereas a heterogeneous foam material may comprise at least one material with different cellular structures (FIGS. 7, 44) or two or more different materials. Two or more different materials may have the same or different cellular structures or sizes. While not intended to be bounded to a theory, it is believed that a foam material with different foam structures and sizes or a heterogeneous foam material may provide the most compact efficiency of cellular structures in a material than a homogeneous foam structure. Apparently, it may be an advantage of heterogeneous foams to have a lower specific gravity, a better thermal insulation property and a lower raw material usage over homogenous foam materials.

Conventional foam materials, such as polystyrene, polyurethane, have been known and widely used as packaging and thermal energy insulation materials for shipping and appliance are considered as homogenous foams. Generally, foam materials are made from a polymeric foam composition in which a blowing agent or a package of blowing agents generates gas bubbles under a heat condition and the gas bubbles are trapped to form a foam during a cooling process. Various foam materials are suitable as a thermal energy insulation material for a substrate of the present invention. Generally, rigid foam materials are preferably suitable, rigid foam materials with closed cells are more preferably suitable, and rigid foam materials with closed cells and heterogeneous cellular structures are most suitable for a substrate of the present invention. In some case when sound damping or insulation property may be required, semi-rigid or flexible foams with open cells may be suitable, too. Typically, a rigid foam material may be obtained from a foam composition comprising, but not limited to, polymers, blowing agents, activators, stabilizers, flame retardants, lubricants, modifiers, co-reactants, pigments, colorants, fillers, UV absorbers, antistatic agents, fungicides, metallic powders, flakes, fibers, special functional additives, cellulous raw materials, renewable raw materials, recycled raw materials, and other additives or modifiers.

The polymers for a foam composition of the present invention may be selected from, but not limited to vinyl homo- or co-polymers, halogenated, halogen or sulfur (HHS) containing vinyl homo or copolymers, polyolefins, HHS containing polyolefin, polyacrylates or HHS containing polyacrylates, poly(alkyl alkyacrylates) or HHS containing poly(alkyl alkyacrylates), polyvinylalkylates or HHS containing polyvinylalkylates, polyvinylidenes or HHS containing polyvinylidenes, polycarbonates or HHS containing polycarbonates, polysulfides or sulfur-containing polymers, polysilicones or silicone containing polymers, sulphur containing polyurethane, polyurethane or HHS containing polyurethane, polyethers or HHS containing polyethers, polyesters or HHS containing polyesters, polyepoxides or HHS containing polyepoxides, alkyds, polyimides, polyamides, urea resins, melamine resin, phenolic resins, polyalkyldiene, asphalts, recycled products, recycled rubbers, recycled plastics, animal proteins, natural oils and products from the oils, lignin, or combinations thereof. Examples are, but not limited to, polyethylene, polypropylene, polystyrene, poly(methyl methacrylate), polyvinyl chloride, poly(vinylidene chloride), polyvinyl acetate, vinyl acetate-ethylene copolymers, Polyethylene terephthalate, polyacrylonitrile, poly(oxyethylene), poly[amino(1-oxo-1,6-hexanediyl)], polyisoprene, polybutadiene, polytoluene diisocyanates, poly(methylene diphenyl diisocyanates) poly(hexamethylene diisocyanates), guar, locust bean gum, corn starch, wheat starch, casein, gelatin, recycled polyethylene terephthalate (PET), recycled polyethylene, recycled polypropylene, recycled polyvinyl chloride, recycled tires. Preferable resins are polyvinyl chloride, chlorinated polyvinyl chloride, polyvinyl acetate-vinyl chloride, polyethylene, polypropylene, polystyrene, polymethyl methacrylate-vinyl chloride, polyethylene terephthalate, poly[amino(1-oxo-1,6-hexanediyl)], polyurethanes, polyesters, alkyds, polyisoprene, polybutadiene, polytoluene diisocyanates, poly(methylene diphenyl diisocyanates) poly(hexamethylene diisocyanates), melamine resins, polyurea, recycled polyethylene terephthalate (PET), recycled polyethylene, recycled polypropylene, recycled polyvinyl chloride, recycled chlorinated polyvinyl chloride, recycled polyvinyl acetate-vinyl chloride, poly(oxyethylene), recycled polyethylene terephthalate, recycled poly[amino(1-oxo-1,6-hexanediyl)], recycled rubbers or tires and vegetable oils and the products and recycled products. More preferable polymer resins are polyethylene, polypropylene, polystyrene, chlorinated polyvinyl chloride, polyvinyl chloride, polyvinyl acetate-vinyl chloride, polymethyl methacrylate-vinyl chloride, polyethylene terephthalate, polyurethanes, polyesters, alkyds, polyisoprene, polybutadiene, polytoluene diisocyanates, poly(methylene diphenyl diisocyanates) poly(hexamethylene diisocyanates), melamine resins, recycled polyethylene terephthalate (PET), recycled polyethylene, recycled polypropylene, recycled polyvinyl chloride, recycled chlorinated polyvinyl chloride, recycled polyvinyl acetate-vinyl chloride, recycled polyethylene terephthalate, recycled rubbers or tires and vegetable oils and the products, and most preferable resins are polyvinyl chloride, chlorinated polyvinyl chloride, polyvinyl acetate-vinyl chloride, polymethyl methacrylate-vinyl chloride, polyurethanes, recycled polyethylene terephthalate, recycled polyethylene, recycled polypropylene, recycled polyvinyl chloride, recycled chlorinated polyvinyl chloride, recycled polyvinyl chloride, recycled polyvinyl acetate-vinyl chloride.

Blowing agents suitable for a foam material include physical blowing agents, chemical blowing agents or mixtures thereof. Exemplary physical blowing agents include hydrocarbons isopentane, monofluorotrichloromethane, dichlorodifluoromethane, chlorofluorocarobons (CFC), hydroxchlorofluorocarbons (HCFC-22, 141), hydrfluorocarbons (HFC134), chlororfluorocarbon-11 (CFC-11), carbon dioxide, nitrogen, helium, argon, and the like. Suitable commercially available physical blowing agents are available from Dupont of Wilmington, Del. under trade names of Formacel S, Z-2 and Z4. Carbon dioxide and nitrogen have been successfully used the physical blowing agents to produce microcellular foams under super critical conditions (1100 pounds per square inch (psi) and 39° C.). Typically, microcellular sizes are preferably less than 100 microns, more preferably less than 50 microns, or most preferably less than 10 microns. Preferred physical blowing agents are isoprene, monofluorotrichloromethane, dichlorodifluoromethane, chlorofluorocarobons (CFC), hydroxchlorofluorocarbons (HCFC-22, 141), hydrofluorocarbons (HFC134), chlororfluorocarbon-11 (CFC-11), carbon dioxide, nitrogen, helium, argon, or mixtures thereof. More preferred physical blowing agents are dichlorodifluoromethane, chlorofluorocarobons (CFC), hydrochlorofluorocarbons (HCFC-22, 141), chlororfluorocarbon-11 (CFC-1), carbon dioxide, nitrogen, helium, argon, mixtures thereof, and most preferred blowing agents are chlorofluorocarobons (CFC), hydrochlorofluorocarbons (HCFC-22, 141), hydrofluorocarbons (HFC134), carbon dioxide, nitrogen, helium, mixtures thereof. Typically, the blowing agents are used in amounts of from about 0.05 to about 10 parts, preferable about 0.1 to about 8 parts, more preferable about 0.1 to about 6 parts, most preferable about 0.2 to about 5 parts per 100 parts of the total compound.

A variety of chemical blowing agents may be suitable for a foam material for a substrate of the present invention. The blowing agent may be an endothermic, exothermic or a combination thereof. None-limiting examples of endothermic blowing agents are polycarbonic acids coated sodium carbonates, bicarbonate, coated citric acids, coated mono sodium citrates, and coated sodium citrates. Exothermic blowing agents include azodicarbonamides, methyl formate, modified azodicarbonamides, azobisformamide (Celogen AZRV), oxybisbenezesulfonyhydrazide (OBSH), p-toluene sulfonyl semicarbizide, toluenesulfonyl-hydrazides (TSH), 5-phenyl)-tetrazole (5-PT), dinitoso, dissipropylhydrazodicarboxylate (DIHC), dinitrosopendamethylene tetramine (DNPT), pentamethylene tetramine, trihydrazinenatriazine. Suitable commercially available blowing agents are available from Mats Corp Ltd of Markham, Ontario under trade names of MS01, CenloMat100, 500 (a carboxylic acid and carbonate products), from Uniroyal Chemical Company, Inc of Middlebury, Conn. under a trade name of Exapandex 5PT (a 5-phenyl tetrazole product), from EPI Environmental Plastics Inc of Conroe, Tex. under a trade name of EPIcore, from Uniroyal Chemical Company of Middlebury, Conn. under a trade name of Expandex, and from Reedy International Corp of Keyport, N.J. under a trade name of Safoam, from Dong Jin under the tradenames of Unicell TS (p-toluene sulfonylsemicarbazide), Unicell OH (p,p-oxybis benzene sulfonyl hydrazide), Unicell 5-PT (5-phenyltetrazole). Azodicarbonamide blowing agents are available in various average particle diameters from Dong Jin as Unicell D-400 (4 μm average diameter); Unicell D-1500 (15 μm average diameter); Unicell D-200 (2 μm average diameter). Typically, the blowing agents are used in amounts of from about 0.05 to about 10 parts, preferable about 0.1 to about 9 parts, more preferable about 0.1 to about 7 parts, most preferable about 0.2 to about 6 parts per 100 parts of the total compound.

While both the physical and chemical blowing agents are useful to make foam materials for a substrate of the present invention, physical blowing agents may tend to give lower foam density or smaller cell sizes under a certain circumstance whereas chemical blowing agents may tend to result in higher foam density or larger cell sizes under a certain circumstance. Cellular sizes may be affected by the particle sizes of a blowing agent. In one embodiment, chemical blowing agents with fine particles sizes, such as commercially available azodicarbonamide Unicell D-200 generally result in smaller cellular structures while others, such as commercially available azodicarbonamide Unicell D-1500 with large particle sizes generally produce larger cellular structures. Generally, the mechanical strength such as tensile strength, compression strength, toughness of a foam material decrease significantly as foam density decreases. However, the smaller the cellular size, the less the decrease of the mechanical strength. Microcellular foams generally have surprisingly excellent toughness, tensile strength, and hardness in comparison with their counterpart non-foamed or macrofoamed materials. Therefore, a foam material with mixed microcellular and macrocellular structures or heterogeneous cellular structures may provide balanced foam properties of low specific gravity, low thermal conductivity, high toughness and tensile strength. A mixed blowing agent package comprising physical and chemical blowing agents or different chemical blowing agents may be suitable for achieving heterogeneous foam materials. Exemplary mixed blowing agents useful for a thermal insulation material for a substrate of the present invention comprise preferably 1 to 99 wt %, more preferably 5 to 80 wt % or most preferably 10-60 wt % of physical blowing agents.

A foam composition may include activator or catalyst to lower the temperature to promote the decomposition reactions of a blowing agent and release gases during a foam formation process. Examples of the activators useful for the present invention are, but not limited to, oxides and salts such as stearates of barium, magnesium, cadmium, calcium, zinc or combinations thereof. Preferable activators are oxides and stearates, organometallic complexes of magnesium, aluminum, cadmium, calcium, zinc or combinations thereof. More preferable activators are oxides and stearates of cadmium, magnesium, calcium, zinc or combinations thereof. Most preferable activators are oxides and stearates of magnesium, calcium, zinc or combinations thereof. An activator is normally added at the concentration of about 0.10 to about 10% by weight, preferably about 0.5 to about 8.0% by weight, more preferably about 1 to about 6.0% by weight and most preferably about 1 to about 5.0% by weight.

A foam composition may also include a nucleating agent or a mixture of nucleating agents. Suitable nucleating agents are those compounds producing sites for bubble initiation as known in the art. A nucleating agent may be a solid material in any form such as particles, flakes, fibrous and the like. Examples are but not limited to, powders of talc, calcium carbonate (CaCO₃), titanium oxide (TiO₂), barium sulfate (BaSO₄), boron nitride calcium silicate, zinc stearate, magnesium stearate, and zinc sulfide (ZnS), organic solids, such as cellulosic fibers, and mixtures thereof. Depending on the particles size, the level of the nucleating agents may be varied. Typically, the level of a nucleating agent is preferably from about 0.1 to about 10 phr, more preferably from about 0.2 to about 8 phr, and most preferably from about 0.5 to about 5 phr.

A foam composition may incorporate a heat stabilizer known to those skilled in the art as the tin stabilizers. Suitable stabilizers include tin salts of monocarboxylic acids such as stannous maleate. Additionally, organo-tin stabilizers such as dialkyl tin mercaptides, carboxylates, and thiazoles may be suitable. Examples of such organo-tin stabilizers include, but not limited to: dibutyltin maleate, dibutyltin dilaurate, di(n-octyl) tin maleate, dibutyltin bis(lauryl mercaptide), bis(dibutyltin isooctylmercaptoacetate) sulfide, bis(monoutyltin-di-isooctylmercatoacetate) sulfide, dibutyltin-di-isooctylmercaptoacetate) (dibutyltinisooctylmercaptoacetate)sulfide, monobutyltin tris(isooctylmercaptoacetate, monobutyltin tris(dodecyl maleate, dibutyltin azelate, dibutyltin bis(benzoate), dibutyltin bis(mercaptoethyl laurate), dibutyltin S,S-bis(isooctyl thioglycoate), dibutyltin β-mercaptoproprionate, di-n-octyltin S,S-bis(isooctyl thioglycolate), and di-n-octyltin β-mercaptoproprionate. Examples of commercially available tin stabilizers include Mark 292-S from Witco Chemical and Thermolite 31 HF from Elf Atochem. Usually, from about 0.1 to about 10 parts by weight of stabilizer per 100 parts by weight of resins may be suitable in a foam composition. More preferably from about 0.5 to 8 or most preferably from about 1 to about 5 parts by weight of a stabilizer per 100 parts by weight of the resins may be added.

In addition to the heat stabilizer, a foam composition may include a co-stabilizer. A co-stabilizer may help reducing the amount of the tin stabilizer needed without reducing the heat deflection temperature of the final foam product. A co-stabilizer may be a metal salt of a phosphoric acid, or other acid acceptors. Specific examples of metal salts of phosphoric acid include water-soluble, alkali metal phosphate salts, disodium hydrogen phosphate, orthophosphates such as mono-, di-, and triorthophosphates of said alkali metals, alkali metal phosphates and the like. Examples of acid acceptors include aluminum magnesium hydroxyl carbonate hydrate such as Hysafe 510, commercially available from the J.M. Huber Company, magnesium aluminum silicates such as Molsiv Adsorbent Type 4A from UOP and alkali metal aluminum silicates such as CBV 10A Zeolite Na-Mordenite by Synthetic Products Co. A preferred costabilizer is disodium hydrogen phosphate. Preferably, from about 0.1 to about 5 parts, more preferably from about 0.3 to about 4 parts, and most preferably from about 0.5 to about 3 parts by weight of the costabilizer are added to the composition per 100 parts by weight of the resins.

A foam composition may optionally include a plasticizer or a mixture of plasticizers to increase the flexibility. Typical plasticizers are compounds of phthalate, epoxidized vegetable oils, low molecular weight polymers or copolymers. Examples of such plasticizers are, but not limited to dimethyl phthalate, diethyl phthalate, dibutyl phthalate, dihexyl phthalate, di-2-ethylhexyl phthalate, di-n-octyl phthalate, di-iso-octyl phthalate, di-iso-nonyl phthalate, di-iso-decyl phthalate, di-iso-tridecyl phthalate, dicyclohexyl phthalate, di-methylcyclohexyl phthalate, dimethyl glycol phthalate, dibutyl glycol phthalate, benzylbutyl phthalate, diphenyl phthalate, epoxidized soybean oils. Of these, dibutyl phthalate, dihexyl phthalate, di-2-ethylhexyl phthalate, di-octyl phthalate, di-iso-octyl phthalate, di-iso-nonyl phthalate, di-iso-decyl phthalate, di-iso-tridecyl phthalate, benzylbutyl phthalate, epoxidized soybean oils may be preferred.

A foam composition may also include a processing aid to provide melt elasticity and strength of the resin melt formed within the extruder and high integrity of the foam cell walls during extrusion. A processing aid may be a high molecular weight polymer, such as, but not limited to homopolymers or copolymers of acrylates, methacrylates, styrene, acrylonitrile, and the like. The molecular weight of the processing aid may be in the range of from 300,000 to 1,500,000. Typically, a polymer with a higher molecular weight may be preferred; resins having a molecular weight of 1,000,000 and higher may be particularly preferred. Examples of those polymers suitable for use in a foam composition of the present invention are those available under trade names of Goodrite 2301×36 from Zeon Company, Blendex 869 from General Electric Plastics, Paraloid K-400, Paraloid K-128N, Paraloid K-125 from Rohm & Haas; and Kaneka PA 10, Kaneka PA 20 and Kaneka PA 30 from Koneka, Tex. The amount of a processing aid may be generally ranging from about 1 to about 20, preferably from about 3 to about 18, more preferably from about 5 to about 15 and most preferably from about 5 to about 10 parts per hundred parts of the resins.

A foam composition may also include a lubricant, a mixture of lubricants, or any lubricants known to those in the art. Suitable lubricants include for example, but not limited to, various hydrocarbons such as petroleum waxes, paraffin waxes (Aristowax 145 available from Unocal), mineral oils (Maxsperse W-6000 and W-3000, available from Chemax Polymer Additives), paraffin oils; polyethylene waxes, polypropylene waxes, PTFE waxes, ethylene vinyl acetate waxes, amide waxes such as ethylene bis-stearamide wax and hydroxyl-stearamide wax, maleated ethylene wax, maleated propylene waxes, microcrystalline waxes, oxidized waxes, wax esters and polycaprolactone waxes, fatty acids such as stearic acid, metal salts of fatty acids such as zinc, magnesium, calcium stearate; esters of fatty acids such as butyl stearate; fatty alcohols, such as cetyl, stearyl or octadecyl alcohol; fatty amides such as stearamide and ethylene-bis-stearamide (commercially available under Loxiol G-70 from Henkel); polyol esters such ad glycerol monostearate, hexaglycerol distearate (commercially available under Glycolube 674 from the Lonza Co.); and mixtures thereof. The amount of lubricants used for a foam composition may vary from application to application and may be determined easily by one of ordinary skill in the art. Preferably from about 0.5 to about 10 parts, more preferably from 0.5 to about 8 parts or most preferably from 1.0 to about 5 parts of lubricants per one hundred parts of the resins may be included in a foam composition.

A foam composition may also incorporate inorganic, organic, metallic, pearlescent pigments, functional pigments or combinations thereof to generate certain properties such as color effects, electrical conductivity and the like. Suitable pigments may be chosen from those known in art. Examples of inorganic pigments are but not limited to, titanium dioxide, carbon blacks, iron oxides, zinc oxide, zinc sulfide, aluminum oxides, lithopone, antimony oxide, barium sulfate, basic lead carbonates, chromium oxides, lead oxides, selenium oxides, spinels such as cobalt blue and cobalt green, Cd (S, Se), ultramarine blue, nano-particle materials, other metal oxides and rare earth metal oxides. In addition to the compounds mentioned so far, other metal and rare earth containing compounds may be suitable. The term rare earth compound will be understood as meaning in particular compounds comprising elements of cerium, praseodymium, neodymium, samarium, europium, gadolinium, terbium, dysprosium, holmium, erbium, thulium, ytterbium, lutetium, lanthanum and yttrium, mixtures. Other preferred rare earth compounds are to be found in EP-A-0 108 023.

Organic pigments such as colorants, dyes may be included for certain color effects. Examples of organic pigments are azo, phthalocyanine, indanthrone, diketo-pyrrolo-pyrrole, quinacridone, perylene, pyrrolopyrrole, anthraquinone, isoindolinone pigments or combinations thereof. Those products are widely available on markets and examples of those products are commercially available under tradenames of Cromophtal, Cinquasia, Irgazin and Irgalite from Ciba. Pearlescent pigments may be incorporated and suitable examples may be, but not limited to, various metal oxide-coated micas or calcium sodium borosilicates and those commercial products available under tradenames of Standart® and Stapa® from Eckart and Sirius® from Novant Corporation. When some special functions such as absorption of high energy radiations such as x, γ-rays, electromagnetic waves shielding are required, those functional pigments may be incorporated. Examples of those functional pigments useful for the present invention include but not limited to powders, particles, fibers, flakes, strips or any forms of electrical conductive materials such as metals of aluminum, copper, zinc, stainless steel, lead, barium, carbon black, graphite, and the like, semi-conductors such as metal oxides, lead oxides, lead salts, barium salts or oxides, ferrites, silicon, germanium, aluminum antimonite, aluminum gallium arsenide, gallium arsenide antimonite nitride, gallium arsenide nitride, boron arsenide, boron phosphide, Indium gallium nitride, Indium gallium arsenide Indium gallium antimonite nitride, Gallium indium arsenide antimonite phosphide, cadmium telluride zinc selenide, cadmium zinc telluride, thallium tin telluride, lead iodide, and the like.

A foam composition may also include a filler or a mixture of fillers to enhance the physical properties or reduce the cost. Suitable fillers are, but not limited to inorganic minerals including natural and processed or modified products, metal oxides, carbonates, silicates, sulphates, sulfides, chlorides, minerals, sands, rocks, cement, and industrial wastes, cellulous materials, synthetic materials, recycled inorganic and polymeric materials, and the like. Examples of those fillers are, but not limited to clay, limestone, calcium carbonate, talc, mica, magnesium oxide, aluminum silicates, magnesium aluminum sulphates, magnesium sulphates, silicates, kaolin, nepheline syenite, calcium metasilicates, silica, sands or processed sands, rocks or processed rocks, coal fly ashes, glass beads, hollow glass spheres, hollow polystyrene or other polymeric beads, hollow plastic spheres, hollow ceramic spheres, perlite, cellulous materials from renewable recourses, synthetic or bio-fibers, chips, recycled plastics, recycled materials from tires, power plant ashes, or combinations thereof. Suitable biofibers may be useful for the present invention including ground wood, sawdust, wood flour, ground newsprint, magazines, books, cardboard, wood pulps (mechanical, stone ground, chemical, mechanical-chemical, refined, bleached or unbleached, virgin or recycled, sludge, waste fines), and various agricultural wastes such as rice hulls, wheat, oat, barley and oat chaff, coconut shells, peanut shells, walnut shells, straw, corn husks, corn stalks, jute, hemp, bagasse, bamboo, flax, and kenaf.

Examples of commercially available fillers suitable for use include, but are not limited to Kaowhite C and EH-44 (Kaolin) available from Thiele Kaolin Company, china clay available from Devkrupa China Clay Corporation, Omycarb FT (calcium carbonate) available from Omya, Inc. and Talc 399 (talc) available from Whittaker, Clark and Daniels, P2015SL (soda lime glass microsphere) available from Prizmallite of Michigan, SC300, 500 (hollow ceramics) available from Schennor Company, and S35, HGS200 (hollow glass bubbles) available from 3M, Nanofil 2, 9 (nano composites) and Cloisites 93A & 30 B and Cloisite NA+ and Cloisite 10A, 15A, 20A (organically modified clays) available from Southern Clay Products, Inc. The amount of a filler material may be generally from about 1 to about 90 parts, preferably from about 2 parts to about 80 parts, and more preferably from about 5 parts to about 70 parts, and most preferably from about 10 parts to about 60 parts by weight, based on 100 parts by weight of the resins.

A foam composition may also include a compound or a mixture of compounds which are interchangeably called as a coupling agent or a compatibility promoting agent to enhance the integrity of the foam materials for better performance, easier processing and/or lower raw material cost. Suitable coupling agents may be those compounds having at least one reactive or associative group or segment from their molecules. Examples of those compounds useful for the present invention may be but not limited to silanes, siloxanes, organometals, amines, aminos, hydroxyl, caroboxyl, organo sulphates or sulphur containing compounds, polyoxyalkylene glycol ethers, acetoacetates, epoxides, isocyanates, acrylates, polyols, polyesters, polyethers, and combinations thereof. Exemplary coupling agents useful for the present invention may be selected from gamma-methacryloxy-propyltrimethoxysilane, gamma-mercaptopropyltrimethoxysilane, vinyltris(2-methoxyethoxy) silane, vinyltrichlorosilane, mercaptoethyltriethoxy-silane, and methylvinyldichlorosilane, diphenyl-dimethoxysilane, gamma-chloropropyltrimethoxysilane, para-tolyltrimethoxysilane, beta-chloroethyltriethoxysilane, and poly(sulfonyl azide) include oxy-bis(4-sulfonylazidobenzene), 2,7-naphthalene bis(sulfonyl azido), 4,4′-bis(sulfonyl azido) biphenyl, 4,4′-diphenyl ether bis(sulfonyl azide) and bis(4-sulfonyl azidophenyl)methane commercially available from Ciba Corporation.

A foam composition may also incorporate a flame retardant or a mixture of flame retardants to increase flame resistance against fire hazards. Suitable flame retardants for the present invention are but not limited to halogenated hydrocarbons, non halogenated compounds and combinations thereof. Halogenated flame retardants may be selected from halogenated aromatic compounds such as halogenated benzenes, biphenyls, phenols, ethers or esters thereof, bisphenols, diphenyloxides, aromatic carboxylic acids or polyacids, anhydrides, amides or imides thereof, polychlorinated biphenyls (PCBs), cycloaliphatic or polycycloaliphatic halogenated compounds, poly-β-chloroethyl triphosphonate mixture, decabromodiphenyl oxide, polybrominated diphenyl ether, pentabromodiphenyl ether (pentaBDE), octabromodiphenyl ether (octaBDE), decabromodiphenyl ether (decaBDE) and hexabromocyclododecane (HBCD), tris(2,3-dibromopropyl)phosphate, tetrabromophthalic acid, tetrabromobisphenol A bis(2,3-dibromopropyl ether) (PE68), brominated epoxy resin; halogenated aliphatic compounds such as halogenated paraffin, oligo- or polymers, chlorendic acid, tetrachlorophthalic acid, tris(2,3-dichloropropyl)phosphate, chlorendic acid derivates (most often dibutyl chlorinates and dimethyl chlorinates), chlorinated paraffin; nitrogen containing compounds such as bis-(N,N′-hydroxyethyl)tetrachlorphenylene diamine, N,N′-(p and m-phenylene)-bis[3,4,5,6-tetrachlorophthalimide], N,N′-(p and m-phenylene)-bis[3,4,5,6-tetrabromophthalimide], N,N′-(methylene-di-p-phenylene)-bis[3,4,5,6-tetrachlorophthalimide], N,N′-(methylene-di-p-phenylene)-bis[3,4,5,6-tetrabromophthalimide], N,N′-(oxy-di-p-phenylene)-bis[3,4,5,6-tetrachlorophthalimide], N,N′-(oxy-di-p-phenylene)-bis[3,4,5,6-tetrabromophthalimide], N,N′-(p and m-tetrachloroxylylene)-bis[3,4,5,6-tetrabromophthalimide], N,N′-bis(1,2,3,4,5-pentabromobenzyl)-pyromellitimide, and N,N′-(p and m-tetrachloroxylylene)-bis[3,4,5,6-tetrachlorophthalimide] in which the tetrahaloxylylene radicals are 1,2,4,5-tetrahaloxylene and 1,3,4,5-tetrahaloxylene radicals. More compounds may be found from those known in the art (U.S. Pat. Nos. 4,579,906, 5,393,812).

Suitable flame retardants may be selected from those none halogenated flame retardants. Examples are but not limited to metal hydroxides or oxides, none metal oxides, various hydrates, borates melamine or nitrogen containing compounds, ammonium compounds, organo phosphates, organo phosphorus compounds, organo sulphates, organo sulphonium compounds, and combinations thereof. Suitable compounds may be selected from but not limited to aluminum hydroxide, magnesium hydroxide, antimony trioxide, red phosphorus, boric acid, borates; melamine cyanurate, melamine borate, melamine phosphates, melamine polyphosphate, melamine pyrophosphate, melamine ammonium polyphosphate, melamine ammonium pyrophosphate, alkylphosphates, alkylisocyanurates, polyisocyanurate, tris-(2-hydroxyethyl)isocyanurate, tris(hydroxymethyl)isocyanurate, tris(3-hydroxy-n-propyl)isocyanurate, triglycidyl isocyanurate; tetrabis(hydroxymethyl)phosphonium salts, tetrakis(hydroxymethyl)phosphonium sulphide, triphenyl phosphate, diethyl-N,N-bis(2-hydroxyethyl)-aminomethyl phosphonate, hydroxyalkyl esters of phosphorus acids, tri-o-cresyl phosphate, tris(2,3-dibromopropyl) phosphate (TRIS), bis(2,3-dibromopropyl) phosphate, tris(1-aziridinyl)-phosphine oxide (TEPA), and combinations thereof. Preferred flame retardants may be but not limited to SAYTEX® RB100 (tetrabromo-bisphenol A) and SAYTEX® BT-93 (ethylene-bis(tetrabromophthalimide) available from Albemarble Corporation, DE-60F (polybrominated diphenyl oxide) and FF680 (1,2-bis(tribromophenoxy) ethane) available from Great Lakes Corporation, PB 370® (tris[3-bromo-2,2-bis(bromomethyl)propyl]phosphate) available from FMC Corporation, DECLORANE PLUS® (bis(hexachlorocyclopentadieno)cyclooctane) available from Occidental Chemical Corporation, Fyrolflex® RDP (tetraphenyl resorcinol diphosphite) available from Akzo Nobel, Exolit AP (ammonium polyphosphate) and Exolit RP (red phosphorus) available from ClariantJJAZZ and PolyFR-100, 106 and 160 (amino phosphates) commercially available from JJI Technologies. Typically, the amount of the flame retardants may be ranging from about 0.5 to about 20 phr, preferably from about 1 to about 18 phr, more preferably from about 2 to about 15 phr, and most preferably from about 2 to about 10 phr.

A foam composition for a substrate of the present invention may also include a second resin or more resins as modifiers to enhance the performance and strength or reduce the raw materials cost. Suitable modifiers may be selected from, but not limited to, thermoplastic resins or a group of resins containing reactive or functional groups such as hydroxyl, carboxyl, silanes, epoxides and the like. Examples of the resins may be but not limited to polyolefin, polyalkylmethacrylates, polyalkylacrylates, polystyrene, copolymers of vinyl acetates and acrylates, polyacrylonitrile, polyethylene terephthalate, poly(oxyethylene), poly(oxypropylene), poly[amino(1-oxo-1,6-hexanediyl)], polyisoprene, polybutadiene, polystyrene-butadiene, and the like. Suitable modifiers containing reactive groups may also be selected from, but not limited to, hydroxyl, carboxyl functional polyesters and alkyds, silane or siloxane containing acrylics or resins, epoxy resins, hydroxyl functional polyethers, phenolic resins, melamine resins, urea-formaldehyde resins, isocyanates, polycyclic carbonates, reactive urethanes, biomass materials such as vegetable oils, rosins, asphalts, and the like. The amount of a modifier may be ranging preferably from about 1 to about 90 wt %, more preferably from about 5 to about 70 wt %, most preferably from about 10 to about 50 wt % in 100 parts of the total foam compound.

A foam composition for a substrate of the present invention may also include a cross linker or a mixture of crosslinkers to enhance the performance and strength or reduce the raw materials cost. Suitable compounds as a crosslinker are but not limited to, compounds containing reactive groups such as peroxide, diene, silane, allyl, thiol, triazine, vinyl, acrylate, metal oxides, organometals, isocyanate, epoxide, carbonate, hydrazide, amine, amino, alkoxyl, carbonyl, carbondiimide, hydroxyl, carboxylic acid, sulphur, and the compounds with mixed reactive groups. Examples of the crosslinkers are but not limited to peroxides, alkyldiene, polycycloalkyliene, silanes, thiolates, triazine containing compounds, lysine, argining, mercapto, metal oxides, organometals, isocyanates, epoxides, melamine resins, phenolic resins, amines, amino containing compounds, polyols, carboxylic acids, sulphur and the like. Preferred crosslinkers are silanes, alkyldiene, polycycloalkyliene, vinyltrialkoxysilane, triazine containing compounds, lysine, argining, metal oxides, organometals, epoxides, melamine resins, phenolic resins, amino-acids and amine containing compounds, and more preferred crosslinkers are lysine, TVCH (1,9-decadiuene) and TAC TMT-3 (triazine) both available from Degussa Corporation, XL-Pearl 60 (vinylalkoxysilane) available from GE Silicones. The amount of a crosslinker may be ranging typically from about 0.1 to 10, preferably from about 0.5 to 8, more preferably from about 0.5 to 5 parts per 100 parts of the resin.

If desired, a foam composition may also include one or more other compounds or additives such as but not limited to surface active agents, antioxidants, UV absorbers, smoke suppressants, biocides, fungicides, mildewcides, antistatic agents, metal releasing agents and the like. These compounds or additives are well known in the art and may be useful. Suitable examples may be, but not limited to, alkane sulfonate, phosphate acid esters, polyalkylated phenols, alkylated polyethylene oxide, alkylated polypropylene oxide, phenols, hindered amines, alkylated phenols, quaternary ammonium compounds, oragnomolybdenum, 2-hydroxybenzophenones, benzotriazoles, phenyl salicylate, triazines, benzothiazolines, stearates, petroleum hydrocarbons, fluoropolymers, silicones, chromium complexes modified long chain fatty acids, and the like. Typical, the amount of these additives is from about 0.1 to about 5 parts per 100 parts of the foam compound.

A suitable foam material as a thermal insulation material for a substrate of the present invention may be a heterogeneous foam material. A heterogeneous foam material comprises heterogeneous foam structures and morphologies and may be prepared using one resin and a package of different blowing agents to generate cells with different cell sizes or structures (FIG. 7, a). For example, a blowing agent package may comprise a physical blowing agent or a mixture of the physical blowing agents such as carbon dioxide, nitrogen, argon and a chemical blowing agent or a mixture of the chemical blowing agents. The physical blowing agents, such as carbon dioxide, may be controlled under a pressure such as more than 1138 pounds per square inches (psi) to generate foam cells less than 100, 50, or 10 microns. The chemical blowing agent or the mixture of chemical blowing agents such as azodicarbonamide, azobisformamide, carbonates with different particles sizes may be activated from 130 C to 190 C to generate large cells up to 5000 microns.

A heterogeneous foam material may also be prepared from two or more different resins. Suitable resins for the present invention may be selected from the same groups of those resins suitable for homogenous foams. Examples may be selected from, but not limited to a group of non-halogenated, halogen or sulfur containing polymers, acrylates, methacrylates, polyacrylates, polyolefin, polyvinyls, polyalkyacrylates, polyesters, polyamides, epoxys, polyesters, phenolic resins, melamine resins, and the like, a group of biomaterials, and a group of recycled materials or industrial wastes from the biomasses and polymeric materials conventionally known to those in the art. Preferred resins have different chemical structures such as polymers with different backbones; side chains or groups for example, polyvinyl chloride versus polystyrene, different physical properties such as crystallinity, solubility, miscibility and the like. Examples of suitable different resin systems are, but not limited to, polyvinyl chloride with polyethylene, polyvinyl chloride with polypropylene, polyvinyl chloride with polystyrene, polyvinyl chloride with polyurethanes, polyvinyl chloride with alkyds, polyurethane with polyethylene, polyurethane with polystyrene and the like.

While resins suitable for the heterogeneous foam materials may have distinct properties or performance, some compatibility promoting agents may be necessary to properly reduce the incompatibility of the resins caused by the structure or property difference so that the resins can synergistically coexist. These compatibility promoting agents may be selected from a groups of ionic or nonionic surface active agents, organophosphates, silane coupling agents, polymeric materials with different structures or polarities where one structure that may be compatible with one resin while another structure may be compatible with the other resin, for example, a styrene-acrylnitrile copolymer may be useful for a heterogeneous system of polyvinyl chloride and polystyrene where polystyrene chain of the styrene-acrylnitrile copolymer may be compatible with the polystyrene resin and the polar polyacrylnitrile may be compatible with polyvinyl chloride; an ethylene-vinyl acetate copolymer may be a useful compatibility promoting agent, too for a heterogeneous system of polyvinyl chloride-polyethylene where the polyethylene chain of the ethylene-vinyl acetate copolymer may be compatible with polyethylene resin and the vinyl acetate chain may be compatible with polyvinyl chloride. The amount of a compatibility promoting agent for a heterogeneous system may vary from system to system. Typical level may be from about 0.1 to about 10 phr, preferably about 0.25 to about 8, more preferably about 0.5 to 6, and most preferably about 1 to 5 phr.

A thermal insulation material for a substrate of the present invention may comprise a skin material (FIGS. 1, 15). A skin material means a layer of performance enhancing materials which may be formed partially or completely on the surfaces of a thermal insulation material for a substrate of the present invention. A layer of performance enhancing materials may be a layer of un-foamed materials, a layer of substantially foam or cells free materials, or a layer of foamed materials with the average cell sizes less than the average cellular size of the foam materials of the substrate. A layer of unfoamed materials or substantially foam or cells free materials may be the same materials as the thermal insulation materials for the substrate or may comprise different materials selecting from, but not limited to coatings, solvent borne coatings, waterborne coatings, powder coatings, and UV curable coatings, polymeric materials, composites of polymers with inorganic materials, metals, biomass, recycled materials, or combinations thereof. A skin material for a substrate of the present invention may comprise a layer of foamed materials with an average cellular size less than the average cellular size of the thermal insulation material for the substrate. Preferably, the average cellular size may be less than 500 microns, more preferably less than 200 microns, or most preferably less than 100 microns.

Depending on the raw material cost, the thickness of a skin material on a substrate may be varied. A skin material on a substrate may preferably have a thickness more than 5 microns, more preferably more than 20 microns, and most preferably more than 50 microns. A substrate for the present invention may have a skin material at least on one side or surface of the substrate, preferably on the two sides, more preferably on all four sides, and most preferably on all the sides and surfaces of the substrate. A number of processing or formation methods may be used to form a skin material for a substrate of the present invention. Examples of suitable methods are but not limited to extrusion, injection, casting, painting, coating, and the like, or combinations thereof. A skin material may be formed stepwisely or concurrently in the same processes of the formation of the substrate.

A thermal insulation material for a substrate of the present invention may also comprise a skeleton structured material (FIGS. 7, 44-47). A skeleton structured material comprises a skeleton structure, a skeleton structure material and a space material within the skeleton structure. A skeleton structure may comprise a framework or skeleton of any three dimensional configuration that provides structural supports within a thermal insulation material. The configuration of a skeleton structure for a substrate of the present invention may be varied as needed and may be selected from, but not limited to a group of configurations whereof the cross-sectional views, perpendicular to the face of the substrate, comprising partial or complete, regular or irregular polygon (triangle, right, equilateral, equiangular, isosceles, scalene, acute, obtuse, quadrilateral, square, rectangle, parallelogram, rhombus, trapezoid, pentagon, hexagon, heptagon, octagon), circle, arc, oval, curved, angular, circular geometric structures, or combinations thereof. The dimensions, such as, the width thickness, or length, of any of a frame, of any particular skeleton structure may be varied as needed to provide a balanced optimal result in terms of supporting performance, raw materials cost and fabrication efficiency.

Suitable skeleton structure materials for a substrate of the present invention may be selected from various materials including foamed and unfoamed materials, inorganic or organic materials, metallic materials, polymeric materials, composites, cellulous materials, biomaterials, recycled materials. For example, suitable polymeric materials may be selected from a group of thermoplastic resins such as but not limited to polyolefins, polyvinyls, polyalkyacrylates, polyesters, polyamides and the like; a group of thermosetting resins such as but not limited to polyesters, epoxys, phenolic resins, melamine resins and the like. Skeleton structure materials may be a cellular or foam material (FIGS. 7, 47). Suitable cellular materials for a skeleton structure material may preferably have an average cellular size less than 4000 microns, more preferably less than 2000 microns, and most preferably less than 1000 microns. A space material suitable for filling the spaces within the skeleton structures for a substrate of the present invention preferably may be a material with a lower specific gravity. Examples of such space materials may be a gaseous material (FIGS. 7, 45) such as air, nitrogen, helium, and the like or a cellular or foam material (FIGS. 7, 46) with lower specific gravidity. A variety of processing methods may be suitable for formation of a skeleton structured material for a substrate of the present invention. Examples of suitable methods may be but not limited to extrusion, injection, casting, cutting, sanding, bonding, or combinations thereof.

A thermal insulation material for a substrate of the present invention may also comprise an electromagnetic wave shielding material. Suitable electromagnetic wave shielding materials for a substrate of the present invention include those electromagnetic wave shielding materials known in the art or those comprising electrically conductive and semi conductive materials. Suitable materials may include those electrical conductive and semi conductive materials with an electrical resistivity less than 10⁸ (Ω-m) at 20° C. Suitable examples of those electrical conductive and semi conductive materials may be selected from, but not limited to a group of metals and alloys such as, but not limited to aluminum, zinc, iron, copper, silver, stainless steel, nickel, chromium, lead; a group of organic conductive materials such as, but not limited to polyacetylene, polyacene, poly(3-hexylthiophene), poly(p-phenylene vinylene); a group of metal coated non-conductive materials such as but not limited to chromium coated glass bead, ceramic, plastics, aluminum coated talc, mica; a group of semiconductors such as, but not limited to carbon black, graphite, metal oxides, ferrites, silicon, germanium, aluminum antimonide, aluminum gallium arsenide, gallium arsenide antimonide nitride, gallium arsenide nitride, boron arsenide, boron phosphide, indium gallium nitride, indium gallium arsenide indium gallium antimonide nitride, gallium indium arsenide antimonide phosphide, cadmium telluride zinc selenide, cadmium zinc telluride, thallium tin telluride, lead iodide, and the like. These electrical conductive and semi conductive materials may be in a continuous form such as foils, film, sheets, plates, woven fabrics, nets and the like or in a discontinuous form such as powders, particles, flaks, fibers, strips, and the like.

For those electrical conductive or semi-conductive materials in a continuous form, an electrical magnetic wave shielding material may be formed on a surface or any inter-surface layer of a substrate by laminating, sandwiching or coating. For example, a metal sheet such as an aluminum sheet or an electrical conductive woven or non-woven material made from carbon fibers or metal coated fibers may be sandwiched between the polymeric materials by hot pressing; a metal film may be formed on a surface of a substrate by electroplating or metal vapor deposition. For those electrical conductive or semi conductive materials in a discontinuous form, an electromagnetic wave shielding material may be formed in a substrate by dispersing those electrical conductive or semi conductive materials such as particles, powders or fibers in a resin media. For example, powders, particles, flakes and shorten fibers of an electrical conductive or semi conductive materials may be added and dispersed into a polymeric foam composition under a temperature and shear to obtain a polymeric dispersion melt and then the resultant thermoforming polymer mix may be processed to form a substrate containing an electromagnetic wave shielding material useful for the present invention.

A substrate of the present invention may directly used as an energy saving, decorative and protective (EDP) material or functioning article for various energy saving, decorative and/or protective purposes. Optionally, one or more protective coatings may be applied before or after installation to enhance the decoration or protection. Suitable protective coatings may be selected from a group of widely and commercially available coatings such as but not limited to solventborne coatings, solution coatings, waterborne coatings, photocurable coatings, powder coatings, and the like on the market or any coatings known in the art.

Desirably, a substrate may be used as a base or back supporting material and further constructed with a functional, decorative and protective (FDP) material or a functional device into various articles to provide enhanced features of energy saving, decoration and protection for various applications. A FDP material or a functional device may be processed and formed on the face of a substrate of present invention through chemical interactions, chemical bondings, physical interactions or combinations thereof between the face materials of the substrate or a contact structure on the face of the substrate and the FDP materials or a functional device. Suitable FDP materials for formation of an article from a substrate of the present invention may be selected from any FDP materials such as, but not limited to coatings, inorganic materials, organic materials, metallic materials, conventional building materials, polymeric materials, or combinations thereof and these FDP materials may be applied manually or automatically and formed on the substrate of the present invention in any order as desired and in any steps as needed.

Preferably, FDP materials for an article based on a substrate of the present invention may comprise conventional building materials, coatings, man-made materials, or combinations thereof to simulate conventional building materials, functional materials capable of providing special functions such as self cleaning, color changing, antigraffiti, antistatic, air-cleaning, and the like, or combinations thereof. Examples of conventional building materials may include, but not limited to, these building materials that have been traditionally used for centuries such as bricks, ceramic tiles, marbles, stones, rocks, glass, concretes, metals, wood and the like in any form such as, but not limited to plates, sheets, films, foils, woven fabrics, networks, strips, fibers, flakes, granules, meshes, particles, powders, or combinations thereof. Various methods may be useful to partially or completely incorporate a conventional building material onto a substrate of the present invention, for example, a conventional building material may be processed into a sheet or plate form in a certain thickness, the building material in a sheet or plate form may be then bonded with or without a contact structure from a substrate with or without an adhesive or by a hot fusion process. Typically, the thickness of a sheet or plat building material may be thick enough to be processed without breakage. For example, these conventional building materials may be processed into a plate or sheet form with the thickness preferably less than 50 millimeters, more preferably less than 30 millimeters, most preferably less than 20 millimeters.

Suitable coatings as the FDP materials for an article may comprise resin binders, carrier medium, crosslinkers, surface additives, pigments, colorants, fillers, biocides, fungicides, viscosity controlling agents, defoamers and the like. Depending on the performance requirements, a coating may be a stain, ink, adhesive, tie-coat, sealer, primer, basecoat or topcoat to provide certain decorative and protective performance and requirements. Formulations in details for each coating may be referred to “Organic Coatings Science and Technology”, Third Edition, published by Wiley Interscience, 2007. Suitable coatings for an article from a substrate of the present invention may be selected from those well known in the art and commercially available solventborne coatings, solution coatings, supercritical fluid coatings, waterborne coatings, photocurable coatings, powder coatings, electrical plating coatings, metal vapor deposition coatings, self-cleaning coatings, anti dirt pick up coatings, anti-dust coatings, electrical deposition coatings, anti electrical static coatings, anti graffiti coatings, color changing coatings, fluorescent coatings smog reduction and elimination coatings, anti corrosion coatings, weatherable coatings, thermoplastic coatings, thermoset coatings, crosslinkable coatings, fluororo carbon coatings, silicone coatings, acrylic coatings, polyurethane coatings, polyester coatings, unsaturated coatings, amide coatings, amino coatings, epoxy coatings, alkyd coatings, phenolic coatings, polyurea coatings, melamine coatings, and combinations thereof. Depending on the end application of the article made from a substrate of the present invention, the coatings may not require stringent photo and weather durability for any interior application whereas the coatings may desirably have excellent photo and weather durability for any exterior application.

Desirably, the coatings as a FDP material for a substrate may contain less volatile components and less hazardous materials. One or more coatings may be selected and applied to achieve certain aesthetic effects and one or more coatings may be selected and applied to perform certain functions such as self cleaning, antigraffiti, antistatic, color changing, air-cleaning or smog, smokes, odors cleaning in addition to decoration and protection. Those functions may be achieved by various methods. For instance, but not limited to those functional components or additives, such as but not limited to photo, heat, moisture or humidity, enzyme activated or induced compounds, may be directly applied or formed into the surface of an article made from a substrate of the present invention or indirectly added into a coating and the resultant coating may be simply used as a decorative and protective material to form an article. For example, an anti-graffiti or self-cleaning coating containing a silicone or fluoride such as an “Easy-On” anti-graffiti coating (Urban Hygiene Ltd., Doncaster, England. DN9 3GA) may be applied as a topcoat to achieve a lasting-clean decorative surface; an ultraviolet light reactive coating containing a photoactivated component such as carbon doped titanium oxide (Kronos VLP7000) may be selected and applied to achieve a decorative and protective surface with a function of reduction or elimination of smog, smokes or any unpleasing odors from the air; a photo-fluorescent coating may be selected and applied to achieve different visual effects such as changing colors under different light conditions.

A coating may be applied on the sides, back and face of a substrate of the present invention by various methods such as, but not limited to, spraying, dipping, spinning, roller-coating, brushing, flood coating, vacuum coating, curtain coating, electrical plating, vapor depositing, and the like. The formation of a decorative and protective film on a substrate of the present invention may require one or multiple coats in one or more coating steps. As desired, a series of coatings may be applied, dried and cured sequentially or in steps onto a substrate of the present invention to form an article with desired decorative and protective performance.

A FDP material may be formed on a substrate to have an artificial pattern of the look and appearance of a conventional building material. Various embossing, hot-fusion, computer-aided printing and coating methods may be suitable for formation of attractive look and appearance of three or two dimensional patterns. For example, a three dimensional pattern of oak wood may be embossed onto a substrate; first the pattern may be copied onto a copy media such as but not limited to stainless steel stamp, plate or roller. The copy media such as the stainless stamp, plate or roller with a pattern, may be heated and imprint the pattern by contacting and hot-pressing onto the face of a substrate. After copying, a three dimensional oak pattern may be retained on the substrate after cooling. Similarly, the look and appearance of a conventional building material may be simulated by a printing process. Preferably, a printing process may be aided with a computer so that any desired pattern may be printed on the substrate. Various printing techniques may be suitable. Examples of a suitable printing method may be selected from but not limited to flexography, offset lithography, screen printing, inkjet printing, digital printing, 3-dementional printing, microlithography, nanolithography, electron beam lithography, maskless lithography, interference lithography, X-ray lithography, extreme ultraviolet lithography, scanning probe lithography and the like. A pattern formed from a printing process on a substrate of the present invention may be a colorful or black and white and may have two or three dimensional esthetic effects. Preferably, simulated images on a substrate may be colorful. After printing, a series of coatings (more details on finishing a product may refer to “Organic Coatings Science and Technology”, Third Edition, published by Wiley Interscience, 2007) may be applied to highlight pattern and enhance the decoration and protection against weathering or degradation.

A FDP material may be formed on a substrate comprising a material made from a conventional building material in conjunctions with an optional coating to simulate appearance of a conventional building material. Some conventional building materials such as, but not limited to brick wall or mortar finish may have their inherent roughness and texture. The surface roughness and texture of those building materials may be simulated by using materials made from those building materials as a filler material in a coating. Preferably, those materials made form conventional building materials may be in a form of, but not limited to, granules, particles, flakes, meshes, or combinations therefore. For example, granular or particulated materials may be made useful by mechanically crashing, grinding, and screening from the conventional building material or the waste of a conventional building material while some conventional building materials may be readily available in form of beads such as glass beads on the market. The shapes of those materials therein may be in a form of any irregular, regular, mixed geometric shapes such as but not limited to fibers, flakes, cubes, cylinders, prisms, globes, beads, and the like. The mean particle sizes may be varied with a pattern to be simulated. Some patterns, for instance a brick look, may require larger mean particle sizes while some patterns for instance a metallic look may require finer mean particle sizes. Various methods may be used to incorporate a material made from a conventional building material into a coating material. For example, a granular material may be dispersed into a coating and the coating containing the granular material may then be applied by flooding, curtain coating to form a decorative and protective layer having the look, appearance and texture of a conventional building material; a granular material may also be spread onto a wet coating on a substrate of the present invention before drying and curing so that the granular material may be effectively embedded on the utmost surface layer of the substrate. If necessary, one or more coatings such as a clear topcoat may be applied over the coating containing the granular materials to further enhance the protection.

A FDP material for a substrate of present invention may be an electromagnetic wave shielding material. Suitable electromagnetic wave shielding materials may be selected from a group of electrical conductive and semi-conductive materials with an electrical resistivity less than 10⁸ (Ω-m) at 20° C. Examples of these electrical conductive and semi-conductive materials may include, but not limited to a group of metals and alloys such as, but not limited to aluminum, zinc, iron, copper, silver, stainless steel, nickel, chromium, lead; a group of organic conductive materials such as, but not limited to polyacetylene, polyacene, poly(3-hexylthiophene), poly(p-phenylene vinylene); a group of metal coated non-conductive materials such as but not limited to chromium coated glass bead, ceramic, plastics, aluminum coated talc, mica; a group of semiconductors such as, but not limited to carbon black, graphite, metal oxides, ferrites, silicon, germanium, aluminum antimonide, aluminum gallium arsenide, gallium arsenide antimonide nitride, gallium arsenide nitride, boron arsenide, boron phosphide, indium gallium nitride, indium gallium arsenide Indium gallium antimonide nitride, gallium indium arsenide antimonide phosphide, cadmium telluride zinc selenide, cadmium zinc telluride, thallium tin telluride, lead iodide, and the like. These electrical conductive and semi-conductive materials may be formed on a surface (face or back) of substrate in a form of foils, films, sheets, plates, woven fabrics, nets and the like by a means of laminating or coating. For example, a metallic sheet such as an aluminum sheet or an electrical conductive woven or non-woven material made from carbon fibers or metal coated fibers may be laminated onto the face of a substrate through an adhesive bonding or hot fusion process; a metallic film may be formed on a surface of a substrate by electroplating or metal vapor deposition coating process. For those electrical conductive or semi-conductive materials in a form of powders, particles, flakes, fibers, strips, and the like, those electrical conductive or semi-conductive materials may be first dispersed in a coating. The resultant coating then may be applied onto the sides, the back, face, or both the face and back and sides as desired, of the substrate to form one or more layers of electromagnetical wave shielding materials. If desired, another or more layers of the electrical conductive or semi-conductive material containing coating and/or one or more decorative and protective coatings may be applied to enhance the electromagnetic wave shielding performance and the decoration and protection. In order to achieve the best result of electromagnetic wave shielding, preferably one surface of a substrate may have one or more layers of an electromagnetic wave shielding material, more preferably all the surfaces and sides of a substrate may have one or more layers of an electromagnetic wave shielding material, and most preferably all the surfaces and sides of a substrate may have one more layers of an electromagnetic wave shielding material and the substrate may also comprise an electromagnetic wave shielding material.

A functional device to be used with a substrate of the present invention to form an article may be a device capable of partially or completely integrating into a substrate of the present invention as a FDP material to form a new functional device in which the substrate is at least the backing and supporting material. The term “device” means a partial or complete working assembly or product entity which can provide a certain function(s), such as, but not limited to a solar-hot water panel to convert solar energy for heating water, a solar light cell to transfer solar lights for lighting inside of a house, a photovoltaic panel to convert solar lights to electricity. Therefore, for example, a suitable functional device for a substrate of the present invention may be, but not limited to a solar thermal panel such as a solar water heater and solar cooling panel, solar lighting cell, or a photovoltaic cell, as available on the market, which may be partially or completely integrated with a substrate of the present invention whereon a new solar energy converting panel is constructed and formed. The term “solar energy converting panel” means a device capable of converting solar energy into any usable energy for direct or indirect heating, cooling, lighting, or electricity. The terms “cell”, “panel”, and “device” herein all means an assembly or unit with a common objective of performing certain functions such as converting solar energy into any usable electricity and may be used interchangeably. In other case, the term “cell” may refer to a smaller unit than a panel or device and a panel or device may comprise one or more cells.

Typically, a solar thermal panel may comprise a solar energy absorbing and converting system, a solar energy transferring system, solar energy storage and application system, and a protective housing and back supporting system. A solar energy absorbing and converting system generally may comprise materials or components absorbing solar energy and converting solar energy for heating or cooling. A suitable solar thermal energy absorbing and converting materials or components may be selected from those known in the art and examples may be black, darken coated metals such as stainless steel, copper, aluminum, carbon steel, sunlight absorbing inorganic materials such as glass, carbon black, ceramic, metal oxides such as antimony tin oxides, tungsten oxide, organic materials such as naphthalimides, phorphyrin, polymeric materials such as polythiophenes, a liquid fluid comprising a solar energy absorbing component such as dyes, carbon black, antimony tin oxide and the like. A solar thermal energy absorbing and converting material or component may be processed into a physical shape of any form such as tubes, hollow plates, and buckets or may be formed and contained in a container such as but not limited to a clear plastic tube, a rubber tube, a glass tube and the like.

A solar energy transferring system may comprise a transfer media to carry any converted solar energy through a moving mechanism to a storage system or application system. Suitable transfer media may be a fluid such as, but not limited to, water, water solutions, anti-freezers or coolants. A moving mechanism may be operational under thermal induced conventional force or motorized force though piping lines. A solar energy storage system may be an energy storage unit such as water tanks comprising an energy storage medium (such as water) and container (such as a tanker). The application system may simply be a residential or commercial energy supply line such as hot water piping lines or hot water tanks. A protective housing and back supporting system for a solar thermal energy panel may be a box unit housing all the absorbing and converting system, partial or complete transferring system and providing protection against weathering and energy loss and providing backing and support to the panel.

For example, a typical passive solar water heating panel comprises a number of darkened metal tubes (as a solar energy absorbing and converting system) which are arranged in a parallel position and housed in a glass covered and insulated supporting panel or box (as a protective housing and back supporting system). The darkened metal tubes containing a heat transfer media, such as water, absorb and convert solar energy for heating water. The heated water is convectionally circulating (as a solar energy transferring system) as it becomes hotter between a water storage tank and the tubes or enters into a supply system (as solar energy storage and application system). For this purpose, a substrate of the present invention may be directly used as the housing and back supporting material for a solar water heating panel, therefore, the housing and back supporting material for a solar water heater may comprise a substrate of the present invention, or a solar thermal panel may be constructed in steps on a substrate of the present invention or formed through bonding on the substrate. A solar thermal energy panel from a substrate of the present invention may be metal frame free and have contact structures on the sides and back for installation. Each solar panel may work independently as a full system including monitoring, controlling and managing apparatus or it may be interconnected to form a larger system to supply solar energy for heating or cooling for applications.

A FDP material for an article from a substrate of the present invention may be replaced with one or more solar lighting cells of those known in the art. The term “solar lighting cell” means a unit that transports exterior sun lights into a building for interior lighting applications and has a function of a conventional lighting source. The resultant panel herein is also a solar lighting panel and may be utilized for various lighting purposes in addition to energy saving, decoration and protection. Desirably, a solar lighting panel may be constructed on a substrate of the present invention to with one or more solar lighting cells. A method to form a solar lighting panel may be varied involving formation of a sunlight collecting unit, transporting unit, illuminating unit, and a backing/supporting, decorative and protective system. A sunlight collecting unit for a panel of the present invention may be selected from but not limited to those conventional sunlight concentrating and focusing units known in the art. A sunlight collecting unit may comprise one or more parabolic dishes of any size and form and may be arranged in various ways on a substrate of the present invention. A suitable sunlight transporting unit may be selected from but not limited to those optic fiber cables in various sizes and forms known in the art. A suitable sunlight illuminating unit may be selected from any of a light exiting apparatus and may be made in various sizes and forms. A solar lighting panel from a substrate of the present invention may be fabricated in steps or prefabricated separately and then formed through bonding on the surface of a substrate. Each panel may work independently as a full system including necessary monitor, controlling and managing apparatus or it may be interconnected to form a larger system to supply solar lighting for the application.

A FDP material for an article from a substrate of the present invention may be replaced with a partial or fully functional solar-electricity or photovoltaic cells or panel. Suitable photovoltaic cells or panels may be selected from, but not limited to, those photovoltaic cells or panels widely known in the art and found commercially available on the market. Typically, those photovoltaic panels comprise a solar energy absorbing and converting system, a solar energy transferring system, solar energy storage and application system, and a protective housing and back supporting system.

A solar energy absorbing and converting system for a photovoltaic panel generally comprise materials or components absorbing solar energy and converting solar energy into electricity. A suitable solar energy absorbing and converting materials or components may be selected from those known in the art and examples may be but not limited to mono-crystal silicon, polycrystalline silicon, amorphous silicon, nano-particles, thin films of semi-conductive materials such as cadmium telluride, copper indium gallium selenide, indium arsenide antimonide, Indium gallium nitride, aluminum indium antimonide, gallium indium arsenide antimonide, cadmium zinc telluride and the like. A solar absorbing and converting material or component may be processed and formed on any prostrate such as glass, plastics, stainless steel, and the like or directly formed on a substrate of the present invention.

A solar energy transferring system may comprise a transfer medium to carry any converted electricity through an electrical circuit to a storage system or power grid. Suitable transfer medium for a photovoltaic panel may comprise positive, negative and grounded insulated conductive wires, conductive pastes, adhesives, connectors in any form, and the like. A solar energy storage system may be an electricity storage unit such as rechargeable batteries or a power grid. The application system may simply be any residential or commercial power supply lines to provide electricity for heating, cooling, lighting or powering any electrical devices and appliances. A protective housing and back supporting system for a solar photovoltaic panel may be a box unit housing all the absorbing and converting system, partial or complete transferring system and providing protection against weathering and energy loss and provide backing and support to the panel.

For example, a typical photovoltaic panel may comprise a number of polycrystalline silicon cells (as a solar energy absorbing and converting system) which are arranged and connected in a manner under a low iron glass and housed and sealed in a supporting box (as a protective housing and back supporting system). The polycrystalline silicon cells absorb and convert solar energy into electricity. The electricity is circulating through the wires and connectors (as a solar energy transferring system) between the cells and rechargeable batteries or a power grid supply system (as solar energy storage and application system). For this purpose, a substrate of the present invention may be directly used as the housing and back supporting material for the photovoltaic panel, the housing and back supporting material for a photovoltaic panel may comprise a substrate of the present invention, or photovoltaic cells may be constructed in steps on a substrate of the present invention or formed through bonding on the substrate. A photovoltaic panel from a substrate of the present invention may be metal frame free and have contact structures on the sides and back for installation. Each photovoltaic panel may work independently as a full system including monitoring, controlling and managing apparatus or it may be interconnected to form a larger system to supply solar energy.

In addition to various features as illustrated from the embodiments in terms of the energy saving from the thermal energy reflecting, insulating, solar energy generating, decoration and protection from the materials having the look and appearance of a conventional building material or other many functions which be added as desired, a article from a substrate of the present invention may be substantially metal frame free. Particularly, those solar energy converting panels from a substrate of the present invention may offer benefits of light weight and better usage of solar exposure areas due to substantially metal frames free in comparison with the conventional solar panels as known in the art. Any article, comprising a substrate of the present invention and a FDP material or a functional device, may have all the necessary contact structures on the sides and the back to simply the installation. As a result, articles from a substrate of the present invention may be installed on any surface of an object in any order or any combinations to render various demands for different energy saving, decoration and protection features. The installation of different articles in certain combination on a surface of an object may present some benefits in terms of the decoration or energy saving efficiency. For example, a solar lighting panel of the present invention may be partially or completely used and installed as a roofing material for a building while a solar thermal panel and photovoltaic panel of the present invention may be partially or completely used and installed as the decorative and protective material on the exterior wall of the building. The lighting generated from the solar lighting panel on the roof may be used for the interior lighting of the building, the heat generated from the solar thermal panel on the exterior wall may be used to heat the water supply system while the electricity generated from the photovoltaic panel on the exterior wall may be used to supply any electrical power needed for control and managing of the solar thermal panel and the water heating system as well as partially or completely supply the electricity needed for the building.

A substrate of the present invention may be partially or completely prefabricated in a plant on an industrial scale or partially prepared or completely installed on site of the application. Similarly, an article from a substrate of the present invention may be partially or completely prefabricated in a plant or partially prepared or completely installed on site of the application. Preferably, a substrate and any article of the present invention may be partially prefabricated in a plant and partially prepared and installed on site of the application; more preferably a substrate of the present invention may be completely prefabricated in a plant on an industrial scale and an article may be partially prepared in a plant and partially prepared on site of application, or most preferably a substrate and article may be completely prefabricated in a plant and installed on site of a application.

A substrate of the present invention may be prepared in any order as desired. For example, a thermal insulation material may be first prepared, one or more contact structures may be then prepared after the thermal insulation material, a decorative and protective material may be prepared in the last step or a decorative and protective material may be first prepared, a thermal insulation material and contact structures may be prepared simultaneously.

An article of the present invention may be prepared in any color as desired. A substrate and an article of the present invention may be prepared in any geometric shape such as but not limited to flat, curve, angular forms, or combinations thereof as desired. A substrate of the present invention may be prepared in any thickness and dimensions. Preferably, the length, width and thickness are from about 1 cm (centimeter), 1 cm (centimeter) and 0.1 cm (centimeter) to about 5000 cm, 1000 cm and 100 cm; more preferably, the length, width and thickness are from about 5 cm, 5 cm and 0.5 cm to about 2500 cm, 500 cm and 50 cm; and most preferably, the length, width and thickness are from about 10 cm, 10 cm and 0.8 cm to about 1500 cm, 200 cm and 25 cm.

An article constructed from a substrate of the present invention and a decorative and protective material or functional device may find various applications. A substrate or article from a substrate of the present invention may be suitable for, but not limited to, various interior or exterior applications on a variety of surfaces of objects such as residential houses, school buildings, commercial high rises, government and institution buildings and the like to achieve energy saving, energy generating, and decoration as well as protection. An article may be used as an exterior decorative an protective panel or material to replace conventional building materials such as but not limited to, bricks, mortar walls, rocks, marbles, glass plates, stainless steel plates, engineered wood panels, medium fiber density boards, vinyl sidings, cement fiber boards and the like to finish the exterior surfaces of a building or house without concerns of cracks and leaking. An article may be used as a solar energy generator for heating, cooling, lighting, and electricity without metal frames. An article may be used as a roofing material to replace the conventional asphalt shingles, metal sheets and shakes, concrete titles, ceramic tiles, stone slabs, polymeric membrane, and the like without nails. An article may be used as interior wall decorative panels to replace gypsum dry wall or plywood panels, and an article may be used as a flooring material to replace vinyl sheets, carpet products, or any wood flooring products, and the like without any nails or screws to punch through. An article may be used as a decking board to replace conventional wood engineered wood, plastic or composite decking board without any nails or screws to punch through.

A number of methods may be suitable to achieve the installation of a substrate or an article from a substrate of the present invention onto any object or any surface of an object in any order. Suitable examples of those objects or surfaces of objects are but not limited to, exterior walls, interior walls, floors, ceilings, roofs, decks for buildings, houses, high rises, transportation vehicles, storages, containers, reactors, appliances, and the like. A suitable method for installation of a substrate or an article based on a substrate of the present invention may be varied. Depending on the contact structures on the sides or on the surface(s) of a substrate of a substrate or article or the purpose of decorations, the installation of a substrate or an article with some contact structures on the sides of a substrate or an article or some substrates or articles may require an optional contact material through indirect contacts for a purpose of providing connections, enhancing the connections, or creating different decorative patterns or combinations thereof. An optional contact material may be an adhesive, sealant, mortar, metal, plastic, wood, composite in any form or any dimension, or a nail, screw, wedges, or combinations thereof. The term “indirect contacts” means the contact structure(s) on the side(s) of one substrate or article may not have any substantial direct contacts with any contact structures on the side(s) of another substrate or article as oppose to “the direct contacts” which require the contact structures on the side(s) of a substrate or article must directly be in contact with a contact structure on the side(s) of another substrate or article in order to form connections.

A suitable method may also be selected based on the property of the surface of an object to be installed. For example, to install an article of the present invention onto those surfaces of buildings which have hard interior or exterior surfaces comprising mortar, concrete, rock, and the like, an adhesive may be suitable and used to bond the article onto the surfaces of the buildings. The term “adhesive” herein means an adhesive that can flow into the contact structures of an article or substrate of the present invention once applied and contacted to form contacts and connections between the surface of an object and the contact structures on the back from the article of the present invention. The adhesive then can be dried, harden, or cured to set and provide final connections and bonding strength to secure the article or substrate onto the surface of the object within a suitable time. Suitable adhesives may be selected from, but not limited to inorganic adhesives, mortars, polymer modified mortars, cement mixes, polymer modified cement mixes such as polyvinyl acetate or polyacrylate modified cement mixes (Quikrete vinyl cement mixes), polymeric adhesives, epoxy adhesives, unsaturated polyester adhesives, polyurethane adhesives, polysilicone adhesives, polyacrylic adhesives, phenoic resins, urea formaldehyde resins, melamine resins, composite adhesives, animal glues, biomass adhesives such as starches, or combinations thereof.

A suitable adhesive for the installation of an article may preferably have a gel time no more than 12 hours and a set or harden time no more than 24 hours, more preferably have a gel time no more than 10 hours and a set or harden time no more than 14 hours, most preferably have a gel time no more than 8 hours and a set or harden time no more than 10 hours. During the installation, an adequate amount of an adhesive such as a polymer modified mortar may be evenly applied onto an exterior wall surface of a building and the contact structures on the back of an article of the present invention, respectively.

Optionally, an adhesive or sealant or such as, but not limited to a weatherable adhesive or silicone sealant (commercially available under trade names of “DAP” Kwik Seal, “OSI Gutter Grip, “GE Silicon Gris” or “Reactor Seal Thread Sealant”) may be applied on the contact structures on the sides of the panel substrate or article of the present invention to provide additional securing and seal properties. A optional bonding enhancing adhesive or material may be applied on the contract structures on the sides, the back, face, or both the back and face of a substrate or article of the present invention to enhance the contacts and connections of the substrate or article to the surface of the object. A suitable optional bonding enhancing adhesive or material may be an adhesive or material which has more affinity or adhesion to the surface material of the contact structures of the substrate or article than the primary adhesive on the surface of the object. By aligning the articles in a direction and allowing all the contact structures to be engaged one by one by applying an pressure with hands against the wall, each article may be installed in a sequence of a choice from the top to the bottom and from the left side to the right side of the building until all the surface of the building is installed and finished with the article of the present invention.

For interior or exterior surfaces of objects or buildings made from non-hard materials such as wood or engineered wood boards or panels, plywood, fiber boards, biomass fiber boards, oriented strand board (OSB), the installation of a substrate or article of the present invention may be accomplished by using a polymeric adhesive such as an epoxy glue. In addition, the installation of a substrate or article of the present invention may be also achieved by using a connection device. The term “connection device” herein means a device comprising a configuration and mechanism which can allow the contact structures on the back of a substrate or an article of the present invention to be fit and engaged with the surface of an object and also has a nail, screw, or other mechanical fastener mechanism to secure the device onto any surface of an object therein. A connection device may be made from any structural material such as, but not limited to a metal, galvanized steel, stainless steel, polymeric materials, plastics such as polyethylene, polypropylene, wood, cellulous containing materials, composites, or and the like. A device may be fabricated into any dimensions as desired to meet any specific needs.

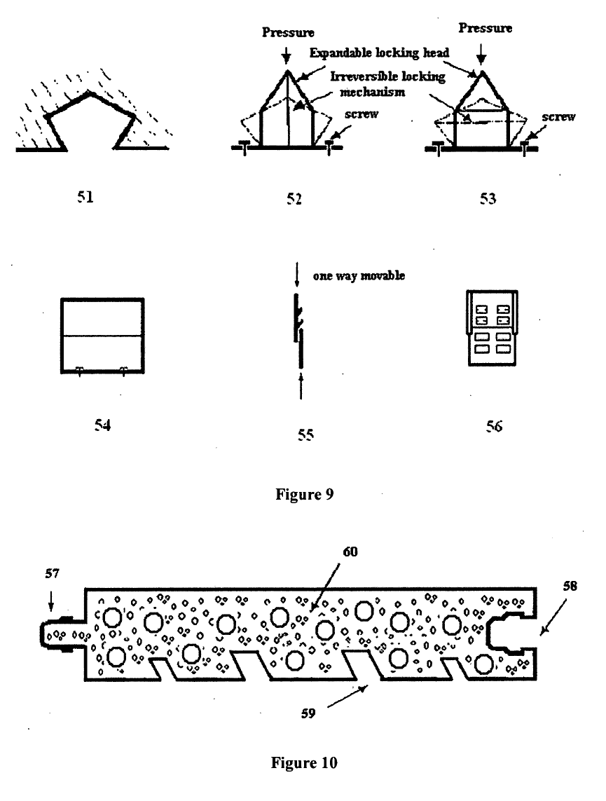

A connection device may comprise any configuration as desired to provide adequate connections and strength to secure to a substrate or an article of the present invention to a surface of an object. Desirably, a suitable connection device may have a “hooking” mechanism or a “self expandable head and/or irreversible locking” mechanism to form a connection or interlock upon a contact with the contact structures of a substrate or article and a surface of an object. For example, a connection device may have a “hook” configuration and mechanism such as, but not limited to “C”, “N”, “S”, “Y” “U” or “V” as shown in FIGS. 8, 49 and 50 in which the connections are provided once inserted and hooked into the contact structures or have a “mushroom” or “self expandable head” configuration and mechanism as shown in FIGS. 9, 52 and 53 in which the self expandable head expands in the contact structures on the back of article or substrate of the present invention under a pressure and the irreversible lock mechanism move in one way only and then lock into the position once moved to a predetermined end position (FIGS. 9, 55, 56) to provide the connections.

During the installation, a connection device may be first fastened and secured onto the surface of an object using nails or screws. Optionally, an adhesive or sealant such as a weatherable adhesive or silicone sealant may be applied onto the contact structures on the sides, back, face or both of the face and back of a substrate or an article of the present invention. By aligning the substrate or articles in a direction and allowing all the contact structures on the sides and the back of the substrate or article to be engaged one by one by applying an pressure with hands against the other neighboring substrates or articles and the surface of the object, each substrate or article may be installed in a sequence of a choice from the top to the bottom and from the left side to the right side of the object such as an building until all the surface of the object or building is installed and finished with the substrate or article of the present invention.

Optionally, one or more protective coatings or materials may be applied before or after installation of a substrate or an article based on a substrate of the present invention to further enhance the decoration or protection. Preferably, suitable protective coatings may be selected from a group of widely and commercially available coatings such as but not limited to solventborne coatings, solution coatings, waterborne coatings, photocurable coatings, powder coatings, and the like on the market or any coatings known in the art.

It will be appreciated that the present invention can take many dimensional, shapes, forms and embodiments. Thus, the following non-limiting examples are intended as illustrations only, since numerous modifications and variations within the spirit and scope of the present disclosure will be apparent to those skilled in the art. Unless otherwise noted, all parts, percentages, and ratios reported in the following examples are on a weight basis, and all ingredients and chemicals used in the examples were obtained, or are readily available, from the chemical suppliers, vendors and market, or may be prepared by conventional techniques.

### EXAMPLES

### Example 1

### Process and Preparation of a Substrate with Different Cellular Structured Foams as the Thermal Insulation Materials and an EDP Panel with the Look and Appearance of Concrete Wall Pattern

Step 1: Substrate with Homogenous and Heterogeneous Foam Structures as the Thermal Insulation Materials and the Preparation

A substrate with a thermal insulation material comprising different foams and skins is processed from PVC (polyvinyl chloride) compounds A and B as shown in Table 1, respectively. Compositions A and B except ingredient HFC134 in composition B are identical. All the ingredients except HFC134 are weighted and added in the order into a bowl mixer (Henshel) with a temperature control less than 150 F. After mixing, the mixture is then dropped through a hopper onto a single screw extruder at a temperature of 130 C and palletized with a strand die. A twin screw extruder (2.5 inch, 32/1 L/D, Akron Extruders, Canal Fulton, Ohio) was used to product a foam material. Physical blowing agent HFC134 is metered and injected into the polymer melt in the extrusion barrel through multiple circumferentially and radically-positioned ports. The screw was designed for a high-pressure injection and mixing of a physical blowing agent and rapid establishment of uniform mixing with the polymer melt into a polymeric solution. The extrusion die designed for a substrate (22.75 cm×3.00 cm) as shown in FIG. 10 contains a pressure drop zone, a heating and cooling zone to control the expansion, cell size and specific gravity of the foam. The temperature profile of the extrusion is maintained at Zone 1 170 C, Zone 2, 180, Zone 3, 185 C and Die 180 and 160 C. A sizer (shaper) with a smooth guide wall inside and substantially the same cross-sectional shape as the die is equipped with vacuum system and a temperature control jacket for heating or cooling to precisely control the skin surface and the geometric shape of the extrudate. The screws are rotated at a rate of 20 RPM (revolutions per minute) to extrude the substrate. After formation and cooling, microscopy and density tests revealed that composition A gave a foam with one cellular structure at an average cell size of 210 microns, a specific gravity of 0.68 g/cm³ (ASTM D-792) and a skin of 270 microns and composition B gave a foam material with two cellular structures one at an average cell size of 160 microns and one at an average cell size of 440 microns a specific gravity of 0.47 g/cm³ and a skin of 250 microns.

Compositions A and B except ingredient HFC134 in composition B are identical. All the ingredients except HFC134 are weighted and added in the order into a bowl mixer (Henshel) with a temperature control less than 150 F. After mixing, the mixture is then dropped through a hopper onto a single screw extruder at a temperature of 130 C and palletized with a strand die. A twin screw extruder (2.5 inch, 32/1 L/D, Akron Extruders, Canal Fulton, Ohio) was used to product a foam material. Physical blowing agent HFC134 is metered and injected into the polymer melt in the extrusion barrel through multiple circumferentially and radically-positioned ports. The screw was designed for a high-pressure injection and mixing of a physical blowing agent and rapid establishment of uniform mixing with the polymer melt into a polymeric solution. The extrusion die designed for a substrate (22.75 cm×3.00 cm) as shown in FIG. 10 contains a pressure drop zone, a heating and cooling zone to control the expansion, cell size and specific gravity of the foam. The temperature profile of the extrusion is maintained at Zone 1 170 C, Zone 2, 180, Zone 3, 185 C and Die 180 and 160 C. A sizer (shaper) with a smooth guide wall inside and substantially the same cross-sectional shape as the die is equipped with vacuum system and a temperature control jacket for heating or cooling to precisely control the skin surface and the geometric shape of the extrudate. The screws are rotated at a rate of 20 RPM (revolutions per minute) to extrude the substrate. After formation and cooling, microscopy and density tests revealed that composition A gave a foam with one cellular structure at an average cell size of 210 microns, a specific gravity of 0.68 g/cm³ (ASTM D-792) and a skin of 270 microns and composition B gave a foam material with two cellular structures one at an average cell size of 160 microns and one at an average cell size of 440 microns a specific gravity of 0.47 g/cm³ and a skin of 250 microns.

TABLE 1
Foam compositions A and B for a substrate

| Item # | Ingredient | A, wt % | B, wt % |
|---|---|---|---|
| 1 | PVC resin (K57) | 100 | 100 |
| 2 | Monomethyltin tris (mercaptethyl tallate) | 2 | 2 |
| | sulfide | | |
| 3 | dibutyl tin dilaurate | 0.25 | 0.25 |
| 4 | Calcium carbonate | 20 | 20 |
| 5 | Titanium dioxide | 5 | 5 |
| 6 | Red Ion Oxide | 2 | 2 |
| 7 | Talc | 1 | 1 |
| 8 | Calcium stearate | 1 | 1 |
| 9 | Acryloid K-400 | 6.5 | 6.5 |
| 10 | Oxidized polyethylene | 0.1 | 0.1 |
| 11 | Paraffin wax | 0.5 | 0.5 |
| 12 | Azobisfomamide (Unicell D-1500) | 0.3 | 0.3 |
| 13 | HFC134 | 0 | 2.0 |

Step 2: Preparation of a Substrate with Contact Structures

After cooling from the ziser, one of the extrudates from Step 1 is cut perpendicularly using a wire-saw into 24.05 centimeters in length. Each of the two fresh sides formed from the cutting is shaped into a square board (22.75 cm×22.75 cm) with a circular saw and a wheel sander into the same outward and inward contact structures as formed from the process in Step 1.

Step 3: Formation of Three Dimensional Patterns to Simulate the Look and Appearance of Concrete Walls

A board prepared from Step 2 is sanded with a sander (P120) to clean the surface. After sanding, the panel is proceeding to an embossing step under a stamp carved with a negative three dimensional pattern of a conventional concrete wall rough pattern. The stamp was made from bronze and carved with concave and convex patterns of a conventional concrete wall. The stamp is heated in an oven (100 C) and applied onto the surface of the board under a pressure to imprint the pattern. After formation of the pattern, the board is allowed to cool down to an ambient temperature for applying decorative and protective coatings. A professional grade of soventborne exterior primer (Rust Oleum) is evenly sprayed and applied (3 wet mils) onto the face and four sides of the substrate board. The board is allowed to dry and then sanded with a brush lone (P180). A lifetime warranty waterborne base coat tinted to a conventional concrete color (Valspar Ultra Premium Duramax) is evenly sprayed and applied (3 mils) over the primer. After completely drying and sanding again (P220), a second coat of the tinted waterborne coating was sprayed (5 wet mils) and applied onto the board. After completely drying, an EDP panel with the look and appearance of concrete wall pattern is prepared (the R value listed in Table 2, ASTM C518).

TABLE 2
Comparison of thermal resistance (R factor) of different
thermal insulation materials

| Sample | Thermal Conductivity (“k”), | Thermal resistivity (“R”), |
|---|---|---|
| Materials | btu/in/hr/sq.ft/° F. | sq.ft × ° F. × in × hr/btu |
| Aluminum | 1000 | 0.001 |
| Glass | 4.7619 | 0.21 |
| Brick | 4.1667 | 0.24 |
| Concrete wall* | 3.8462 | 0.26 |
| Example 1 A | 0.2625 | 3.81 |
| Example 1 B | 0.2203 | 4.54 |
| Example 2 | 0.1832 | 5.46 |
| Example 3 | 0.2370 | 4.22 |
| Example 4 | 0.1972 | 5.17 |

*Sample prepared from conventional Portland cement mix (1 part cement/2 parts sand/3 parts gravel)

### Example 2

### Process and Preparation of a Substrate with a Skeleton Structured Thermal Insulation Material and an EDP Panel with Thermal Reflecting and Electromagnetic Wave Shielding Materials and Appearance of Bricks

Step 1: A substrate with a Foam Filled Skeleton Structured Material and the Preparation

A substrate with a thermal insulation material comprising a skeleton is formed from PVC (polyvinyl chloride) composition C as shown in Tables 3 and 4.

All the ingredients in Table 3 are weighted and added in the order into a bowl mixer (Henshel) with a temperature control less than 150 F. After mixing, the mixture is then dropped through a hopper onto a single screw extruder at a temperature of 130 C and palletized with a strand die. A twin screw extruder (2.5 inch, 32/1 L/D, Akron Extruders, Canal Fulton, Ohio) with a modified screw design is used to process the composition. The die designed for a substrate (22.75 cm×3.00 cm) as shown in FIG. 11 is a crosshead die to receiving injected liquid foam as well as the extrudate. The liquid foam (Table 4) is a rigid polyurethane foam material, D and becomes expanded upon mixing of D1 and D2 and contacting the extrudate inside the skeleton structure. The temperature profile of the extrusion is maintained at Zone 1 170 C, Zone 2, 180, Zone 3, 185 C and Die 160 C. A sizer (shaper) with a smooth guide wall inside is equipped with a vacuum system and a temperature control jacket for heating or cooling to precisely control the skin surface and the shape of the extrudate. The extrusion is proceeding as the liquid foam is simultaneously injected to form a polyurethane foam filled skeleton structured board. Density tests revealed that composition D give the board with a specific gravity of 0.36 g/cm³.

TABLE 3
Composition C for a skeleton material

| Item # | Ingredient | C, wt % |
|---|---|---|
| 1 | PVC resin (K57) | 100 |
| 2 | Monomethyltin tris (mercaptethyl tallate) sulfide | 2 |
| 3 | Calcium carbonate | 20 |
| 4 | Titanium dioxide | 5 |
| 5 | Yellow Ion Oxide | 2 |
| 6 | Talc | 1 |
| 7 | Calcium stearate | 1.2 |
| 8 | Acryloid K-400 | 6.5 |
| 9 | Oxidized polyethylene | 0.1 |
| 10 | Paraffin wax | 0.8 |

All the ingredients in Table 3 are weighted and added in the order into a bowl mixer (Henshel) with a temperature control less than 150 F. After mixing, the mixture is dropped into a single screw extruder at a temperature of 130 C and palletized with a strand die. A twin screw extruder (2.5 inch, 32/1 L/D, Akron Extruders, Canal Fulton, Ohio) with a modified screw design is used to process the composition. The die designed for a substrate (22.75 cm×3.00 cm) as shown in FIG. 11 is a crosshead die to receiving injected liquid foam as well as the extrudate. The liquid foam (Table 4) is a rigid polyurethane foam material, D and becomes expanded upon mixing of D1 and D2 and contacting the extrudate inside the skeleton structure. The temperature profile of the extrusion is maintained at Zone 1 170 C, Zone 2, 180, Zone 3, 185 C and Die 160 C. A sizer (shaper) with a smooth guide wall inside is equipped with a vacuum system and a temperature control jacket for heating or cooling to precisely control the skin surface and the shape of the extrudate. The extrusion is proceeding as the liquid foam is simultaneously injected to form a polyurethane foam filled skeleton structured board. Density tests revealed that composition D give the board with a specific gravity of 0.36 g/cm³.

TABLE 4
Composition D for a liquid foam

| Item # | | D, wt % |
|---|---|---|
| | Resin component, D1 | |
| 1 | Polyether polyol | 55 |
| 2 | Polyester polyol | 45 |
| 3 | Byk W9010 | 1.0 |
| 4 | Silbyk 9215 | 1.5 |
| 5 | Fyrolflex ® RDP (tetraphenyl resorcinol | 2 |
| | diphosphite) | |
| 6 | Electrical conductive carbon black | 9 |
| 7 | Fly ash | 10 |
| 8 | Talc | 5 |
| 9 | Mineral oil | 1 |
| 10 | Amine catalyst | 0.3 |
| 11 | 2,2′-dimorpholino-diethyl ether | 0.8 |
| 12 | water | 3.0 |
| | Curing agent component, D2 | |
| 1 | MDI | 110 |
| 2 | Fumed Silica | 2 |
| 3 | Silbyk 9215 | 0.4 |

Step 2: Preparation of a Substrate with Contact Structures

After cooling from the ziser, the extrudate from step 1 is cut perpendicularly using a wire-saw into 17.75 centimeters in length. The resultant panel has one pair of the outward and inward contact structures on two sides of the panel. Similarly, following step 1, composition C in Table 3 is used to extrude a side contact structure profile as shown in FIG. 12 comprising the same outward and inward contact structures. After cooling, the extrudate is first longitudinally bisected along the bisecting line and then crosswisely cut into 22.75 in length. Each of the fresh surfaces from cutting is then subjected to sanding (P120 and P180). After sanding, each of the bisected contact structure strips is bonded with an quick set epoxy adhesive under a pressure (1 psi) to the other two sides of the board that do not have an extruded structure of the board to afford a substrate with one outward contact structure on the two sides and one inward contact structure on the other two sides of the board.

Step 3. Preparation of Thermal Reflecting and Electromagnetic Wave Shielding Material

Both the back and face of the substrate are sanded (P220) to prepare the surfaces for boning and coating. A quick set clear liquid epoxy adhesive is evenly spayed (1 dry mil) onto the back and face of the substrate from Step 2. After drying, a vinyl sandwiched aluminum sheet (long 22.95 cm×wide 22.95 cm×thick 100 microns) with the original silver shining surface facing up against the substrate is evenly rolled and laid onto the back and face of the substrate, respectively. The areas of the aluminum sheet covered on the contact structures on the back are partially separated using a knife to allow the contact structures exposed and the separated aluminum sheet areas are then rolled down to the inside of the contact structures so that the separated portions of the aluminum can be useful against radiant heat loss and for improvement of electromagnetic wave shielding. After the adhesive becomes set, a substrate comprising thermal reflecting and electromagnetic wave shielding materials is prepared.

Step 4. Formation of a Three Dimensional Pattern to Simulate the Look and Appearance of Conventional Bricks

A professional grade of epoxy primer (Rust Oleum) is sprayed and applied (3 wet mils) on the face of substrate from Step 4. Red bricks or waste red bricks are smashed and grinded into granular particles into 8 to 15 meshes. After drying and curing, the primer is sanded (P120) and a lifetime warranty waterborne basecoat (Duration Sherwin William) tinted to the red brick color is sprayed and applied (5 wet mils) onto the primer. A frame mold is made from a plastic plate to form the outlines of a negative pattern (the mortar area is covered and the brick area is opened) of a brick wall and placed immediately over the wet coating. A layer of the granular particles of the red bricks are evenly spread over the open areas of the mold while the basecoat is wet. After drying, the frame mold is removed and another frame mold made from a plastic plate to form the outlines of a positive pattern (the mortar area is opened and the brick area is covered) of a brick wall is accurately placed back to the location where the first frame mold was placed. A waterborne flat basecoat with a lifetime warranty (Duration Sherwin William) tinted to the conventional mortar color is sprayed over the frame mold (5 wet mils). A layer of the coarse sand particles (20 to 30 meshes) are evenly spread over the open areas of the mold while the basecoat is wet to simulate a pattern of the conventional mortar rectangular joints. After drying and the frame mold is removed, a flatted clear waterborne coating with a lifetime warranty (Duration Sherwin William) is sprayed and applied (5 wet mils) over the substrate. After completely drying, an EDP panel (22.75 cm by 22.75 cm) with thermal reflecting and electromagnetic wave shielding materials as well as appearance of a red brick wall finish is afforded (the R value listed in Table 2, ASTM C518).

### Example 3

### Process and Preparation of an EDP Panel with Appearance of Glass

A substrate prepared from Step 2 of Example 1, B is sanded (P120). After sanding, a layer of a quick set adhesive tinted to dark blue (Dow Corning Q3-6093 Weatherable Silicone Adhesive) is applied (5 mils) onto the face and sides of the substrate, and a tempered glass plate (22.75 cm×22.75 cm×0.32 cm) is laid over the adhesive on the face of the substrate. While the adhesive is wet, the glass plate is evenly applied with a pressure (2 psi, pounds per square inches) on the top to allow any air bubble to flow out and the adhesive to cure. After the adhesive is set, a frameless EDP panel with the look and appearance of glass is prepared (the R value listed in Table 2, ASTM C518).

### Example 4

### Process and Preparation of a Substrate from Cast Molding and an EDP Panel with a Solid Oak Finish

Step 1. Preparation of the Board Substrate

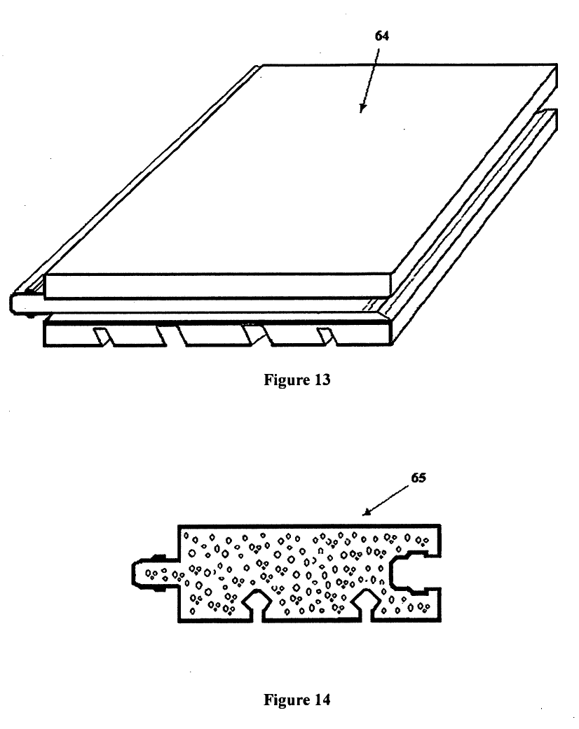

A six piece detachable mold is used to cast mold a substrate (22.75 cm×22.75 cm×3.00 cm) as shown in FIG. 13. A silicone mold releasing agent is uniformly sprayed on the inside surfaces of the mold. After drying, a non-foaming polyurethane composition (Table 5, E) after mixing E1 with E2 is evenly sprayed and applied (5 mils) to the inside surface of the mold and allowed to dry and cure for 30 minutes. After drying and curing, a foaming polyurethane composition (Table 5, F) after mixing F1 with F2 is immediately poured into the mold at a room temperature. The mold is immediately closed following the addition to allow foaming and solidifying for 60 minutes to afford a rigid polyurethane foam substrate (specific gravity at 0.51) with the contact structures on the sides and back of the substrate.

TABLE 5
Composition E and F for a liquid polyurethane and foam polyurethane

| Item # | Component 1 | E1, wt % | F1, wt % |
|---|---|---|---|
| 1 | Polyether polyol | 55 | 55 |
| 2 | Polyester polyol | 45 | 45 |
| 3 | Byk W9010 | 1.0 | 1.0 |
| 4 | Silbyk 9215 | 0 | 1.5 |
| 5 | Fyrolflex ® RDP (tetraphenyl | 2 | 2 |
| | resorcinol diphosphite) | | |
| 6 | carbon black | 1 | 1 |
| 7 | Calcium carbonate | 20 | 20 |
| 8 | Talc | 5 | 5 |
| 9 | Mineral oil | 0 | 1 |
| 10 | Water | | 3.5 |
| 11 | Amine catalyst | 0 | 1.3 |
| 12 | Tin catalyst | 0.10 | 0 |
| 13 | 2,2′-dimorpholino-diethyl ether | 0.1 | 0.8 |
| 14 | Butyl acetate | 200 | 0 |

| | Curing agent component 2 | E2, wt % | F2, wt % |
|---|---|---|---|
| 1 | MDI (4-isocyanatophenyl) methane | 90 | 123 |
| 2 | Fumed Silica | 2 | 2 |
| 3 | Silbyk 9215 | 0.4 | 0.4 |

Step 2. Formation of Protective and Decorative Materials

The face and sides of the substrate from Step 1 is sanded (P180). After cleaning, a layer of a quick set adhesive (Dow Corning Q3-6093 Weatherable Silicone Adhesive) is applied (6-8 mils) onto the face and sides of the substrate. After flowing and leveling of the adhesive, an oak veneer (22.75 cm×22.75 cm×0.32 cm) is laid over the adhesive on the face of the substrate. While the adhesive is wet, the oak veneer is evenly applied with a pressure (2 psi) on the top to allow any air bubble to flow out and the adhesive to cure. After the adhesive is set, the veneer surface is sanded (P220). After removing the dust, a Cabot® Water-Borne PolyStain (Valspar Cabot) is uniformly applied with a brush (2 mils) on the face and sides and allowed to dry for 45 to 60 min at an ambient room temperature (25 C). After drying, the stain coat is sanded (P320) and another coat of Cabot® Water-Borne PolyStain is applied (1-2 mils). After drying, two clear protective coats (Valspar Faux Clear Protector) are applied (3 mils each coat) by spray with sanding (P320) between the coats. After the final drying, an EDP panel with a solid oak finish is afforded (the R value listed in Table 2, ASTM C518).

### Example 5

### Process and Preparation of a Photovoltaic Panel

A polycrystalline silicon photovoltaic cell assembly (2.2 volts 2×2) fabricated on a tempered glass without a backing glass and metal frame is used as a FDP material. A substrate from Step 1 of Example 4 is used as the backing substrate for the backing and supporting of the photovoltaic cells on the prostrate and sanded (P120) to prepare the surface. A quick set weatherable silicon adhesive is applied by a brush on the face (8-10 mils) and sides (3-4 mils) of the substrate. Two electrical conducting plates connecting to the photovoltaic cell assembly are embedded in the substrate with two connecting wires to the back of the substrate. With a uniform pressure (0.2 psi), the photovoltaic assembly is evenly placed against the wet adhesive on the top of the substrate and allowed to be bonded completely. After the adhesive is set, an EDP panel with photovoltaic cells without any metal frame is prepared.

### Example 6

### Process and Preparation of a Non-Screwing and Nailing Decking Board

Step 1. Preparation of a Decking Board Substrate

A polyvinyl chloride foam composition is used to make a decking board substrate and the composition is shown in Table 6. All the ingredients are weighted and added in the order into a bowl mixer (Henshel) with a temperature control less than 150 F. After mixing, the mixture is then dropped through a hopper onto a single screw extruder at a temperature of 130 C and palletized with a strand die. A twin screw extruder (2.5 inch, 32/1 L/D, Akron Extruders, Canal Fulton, Ohio) is used to process the composition. The extrusion die designed for the decking board substrate (13.97 cm×2.54 cm) as shown in FIG. 14 contains a pressure drop zone, a heating and a cooling zones to control the cell size and foam specific gravity. The temperature profile of the extrusion is maintained at Zone 1 170 C, Zone 2, 180, Zone 3, 185 C and Die 180 and 168 C. A sizer (shaper) with a smooth guide wall is equipped with vacuum system and a temperature control jacket for heating or cooling to precisely control the skin surface and the geometric shape of the extrudate. The screws are rotated at a rate of 26 RPM to form the board substrate. Microscopy and density tests revealed that composition G gave a foam material with one cellular structure at an average cell size of 340 microns, a specific gravity of 0.64 g/cm³ (ASTM D-792) and a skin of 670 microns.

Step 2. Formation of a Decking Board with Oak Appearance

A board prepared from step 1 is proceeded to an embossing step where an emboss roller was carved with a negative three dimensional pattern of an oak appearance. The roller is heated (112 C) with a temperature controller and roll over the substrate face to print the pattern on the substrate under a pressure. After formation of the pattern, the board is cooled down to an ambient temperature to give a decking board with the look and appearance of oak wood.

TABLE 6
A rigid foam composition G for a decking board substrate

| Item # | Ingredient | G, wt % |
|---|---|---|
| 1 | PVC resin (K57) | 100 |
| 2 | Monomethyltin tris (mercaptethyl tallate) sulfide | 2.5 |
| 3 | dibutyl tin dilaurate | 0.25 |
| 4 | Fly ash | 35 |
| 5 | Titanium dioxide | 2 |
| 6 | Red Ion Oxide | 2 |
| 7 | Carbon black | 0.2 |
| 8 | Talc | 1 |
| 9 | Calcium stearate | 2 |
| 10 | Acryloid K-400 | 6.5 |
| 11 | Oxidized polyethylene | 0.5 |
| 12 | Paraffin wax | 0.9 |
| 13 | Azobisfomamide (Unicell D-1500) | 0.5 |

All patents, applications and literature cited are hereby incorporated by reference as if individually incorporated. In the case of any inconsistencies, the present disclosure, including any definitions therein will prevail. The present invention has been described herein with respect to examples, techniques and preferred embodiments thereof. However, it should be understood that this invention is not limited to any embodiment set forth above and the foregoing description is intended to be illustrative and not restrictive. Those skilled in the art will realize that various modifications may be made in form and detail without departing from the spirit and scope of the disclosure and will readily appreciate that the teachings found herein should be applied to other embodiments within the scope of the claims hereto attached.

1. A substrate comprising:
at least one contact structure at least on one side of the substrate and
at least one contact structure at least on the back, face or both, the back and face of the substrate.

2. A substrate according to claim 1, wherein the contact structure comprises:
an outward contact structure of an erected three dimensional configuration whereof the cross-sectional view, perpendicular to the face, comprises a partial or complete, regular or irregular polygon, arc, angular, oval, curved, circular geometric structure, or combinations thereof;
an inward contact structure of a recessed three dimensional configuration whereof the cross-sectional view, perpendicular to the face, comprises a partial or complete, regular or irregular polygon, arc, angular, oval, curved, circular geometric structure, or combinations thereof; or
combinations thereof.

3. A substrate according to claim 1 or 2, wherein the contact structures comprise:
a secondary outward contact structure of an erected three dimensional configuration whereof the cross-sectional view, perpendicular to the face, comprises a partial or complete, regular or irregular polygon, arc, angular, oval, curved, circular geometric structure, or combinations thereof;
a secondary inward contact structure of a recessed three dimensional configuration whereof the cross-sectional view, perpendicular to the face, comprises a partial or complete, regular or irregular polygon, arc, angular, oval, curved, circular geometric structure, or combinations thereof; or
combinations thereof on the primary contact structures.

4. A substrate according to any of claims 1 to 3, wherein a contact structure on one side of a substrate and a contact structure on one side of another substrate form a connection upon direct or indirect contacts.

5. A substrate according any of claims 1 to 4, wherein the contact structure on the back, face, or both the back and face of the substrate comprises a configuration that the inner cross-sectional area, parallel to the surface of the substrate, of an inward contact structure inside the substrate is equal to, bigger, or smaller than the outer cross-sectional area, parallel to the same surface of the substrate, of the same inward contact structure on the surface of the substrate.

6. A substrate according any of claims 1 to 4, wherein the contact structure on the back, face, or both the back and face of the substrate comprises a configuration that the upper cross-sectional area, parallel to the surface of the substrate, of an outward contact structure is equal to, bigger, or smaller than the lower cross-sectional area, parallel to the same surface of the substrate, of the same outward contact structure on the surface of the substrate.

7. A substrate according to any of claims 5 to 6, wherein the contact structure on the back, face or both the back and face of the substrate comprises a configuration thereof one of the angles forming, between one surface of the contact structure and the back or face of the substrate, is smaller than 90 degree.

8. A substrate according to any of claims 1 to 7, wherein the substrate includes a thermal insulation material comprising at least two materials selecting from a thermal energy reflecting material, a homogeneous foam material, a heterogeneous foam material, a skin material, a skeleton structured material, an electromagnetic wave shielding material.

9. A substrate according to any of claims 1 to 7, wherein the substrate comprises at least one material being flame resistant, containing a flame or fire retardant, crosslinked material, or a recycled material.

10. A substrate according to any of claims 1 to 9, being constructed to an article having at least one contact structure at least on one side and at least one contact structure at least on the back, face, or both the back and face of the substrate.

11. An article according to claim 10, comprising:
a substrate in accordance to any of claims 1 to 10 and
a functional, decorative and protective material or a functional device.

12. An article according to claim 11, wherein the functional, decorative and protective material comprises a coating, a material having the look and appearance of a conventional building material; a thermal energy reflecting material; an electromagnetic wave shielding material; an air cleaning material; a color changing material, a solar-thermal energy converting material; a solar-lighting material; a solar-electricity converting material; or combinations thereof.

13. An article according to claim 12, wherein the material having the look and appearance of a conventional building material is a conventional building material, a material made with an artificial pattern of a conventional building material, or combinations thereof.

14. An article according to claim 13, wherein the material made with an artificial pattern comprises one or more materials having one or more artificial patterns made from a process comprising at least one process selecting from roller embossing, pressing, stamping, molding, printing, coating processes to simulate a pattern of a conventional building material.

15. An article according to claim 12, wherein the solar-thermal energy converting material, solar-lighting material, or the solar-electricity converting material comprises any necessary materials to form a solar energy converting panel in any order or form on a substrate in accordance with any of claims 1-10 and convert solar energy into any usable energy for heating, cooling, lighting, electricity or combinations thereof.

16. An article according to claim 11, wherein the functional device comprises partial or complete solar-thermal energy converting cells or device, solar-lighting cells or device, or photovoltaic cells or device.

17. An article according to any of claims 15 to 16, being a solar energy converting panel or device with contact structures on the sides and contact structures on the back of the panel.

18. A method for providing an energy saving, decorative and protective finish on an object comprising the steps of:
providing an object or surface of an object; and
applying an optional sealant on the sides and/or an adhesive and/or an optional bonding enhancing adhesive into both the contact structure(s) on the back of a substrate or an article in accordance of any of claims 1-17 and the surface of the object, or securing a connection device onto the surface of the object, or combinations thereof; and
applying an optional contact material onto the contact structures on the sides of the substrate or article;
securing the substrate or article by
applying an optional contact material onto the contact structures on the sides of the substrate or the article;
connecting the contact structures on the sides of the substrate or the article to the contact structures on the sides of any neighboring substrates or articles; and
connecting the contact structures on the back of the substrate or the article to the adhesive, the connection device, or combinations of the adhesive and connection device on the surface of the object;
applying one or more optional protective coatings over the installed substrate or the article.

19. A connection device according to claim 18, for providing connections or interlocks to a
substrate or an article in accordance with any of claims 1 to 17, comprising a “hooking” or a “self expandable head and/or irreversible locking” configuration and mechanism to form a connection or interlock upon contacts with the contact structures on the back of the substrate or article and the surface of an object.

20. A finished object having an energy saving, decorative and protective finish comprising:
providing a surface of an object or object; and
an adhesive, optional sealant, optional bonding enhancing adhesive, connection device, and/or combinations thereof, and
a substrate in accordance with any of claims from 1 to 9, and/or
an article or different articles in any combinations in accordance with any of claims from 10 to 17; and
an optional contact material and/or an optional protective coating.
